(19) United States
(12) Patent Application Publication
(10) Pub. No.: US 2026/0090171 A1
(43) Pub. Date: Mar. 26, 2026

(54) ELECTRONIC DEVICE AND METHOD OF MANUFACTURING ELECTRONIC DEVICE

(71) Applicant: Samsung Display Co., Ltd., Yongin-si (KR)

(72) Inventors: JEONGMIN BAN, Yongin-si (KR); YOUNGMIN CHO, Yongin-si (KR); YEWON CHO, Yongin-si (KR); DONGJIN JEONG, Yongin-si (KR)

(21) Appl. No.: 19/320,491

(22) Filed: Sep. 5, 2025

(30) Foreign Application Priority Data
Sep. 24, 2024 (KR) 10-2024-0128708

(51) Int. Cl. H10H 29/85; H10H 29/01; H10H 29/852

(52) U.S. Cl. CPC H10H 29/8508; H10H 29/012; H10H 29/0362; H10H 29/852

(57) ABSTRACT

An electronic device includes a foldable folding area and a first non-folding area and a second non-folding area spaced apart from each other with the folding area interposed therebetween. The electronic device includes: a display module including a display area, a non-display area disposed outside the display area, and a bending area disposed on one side of the non-display area and bent with respect to an imaginary bending axis extending in one direction; a protective layer including a main protective layer overlapping the display area under the display module and a sub-protective layer spaced apart from the main protective layer and overlapping the bending area; and a reinforcing layer overlapping the display module, spaced apart from the main protective layer and disposed between the main protective layer and the sub-protective layer.

This application claims priority to Korean Patent Application No. 10-2024-0128708, filed on Sep. 24, 2024, and all the benefits accruing therefrom under 35 U.S.C. § 119, the content of which in its entirety is herein incorporated by reference.

### BACKGROUND

Embodiments of the present disclosure described herein relate to an electronic device and a method of manufacturing an electronic device, and more particularly, relate to a foldable electronic device including a reinforcing layer in a bending area.

Various types of electronic devices are being used to provide image information, and these electronic devices include a display module divided into a display area and a non-display area. A plurality of pixel areas are defined in the display area, and a circuit element for controlling the pixel areas in the display area, a signal wiring line, or a pad part connected to a driving circuit board are arranged in the non-display area. An area in which the pad part or the like is disposed may be fixed in a bent state.

Meanwhile, a bending stress may be provided to an exposed portion of a bending part, and development of a protective member structure for various members for protecting the bending part and a method of providing these protective members is required.

### SUMMARY

Embodiments of the present disclosure provide an electronic device in which a reinforcing layer structure that improves durability of a bending area in which a signal wiring line or the like is disposed and minimizes damage to other components even in a folding operation is introduced.

Embodiments of the present disclosure also provide a method of manufacturing an electronic device for introducing a reinforcing layer to improve durability of a bending area in which a signal wiring line or the like is disposed in a display module.

According to an embodiment, an electronic device includes a foldable folding area and a first non-folding area and a second non-folding area spaced apart from each other with the folding area interposed therebetween, the electronic device including a display module including a display area, a non-display area disposed outside the display area, and a bending area disposed on one side of the non-display area and bent with respect to an imaginary bending axis extending in one direction, a protective layer including a main protective layer overlapping the display area under the display module and a sub-protective layer spaced apart from the main protective layer and overlapping the bending area, and a reinforcing layer overlapping the display module, spaced apart from the main protective layer and disposed between the main protective layer and the sub-protective layer.

A separation distance between the main protective layer and the reinforcing layer may be 50 micrometers (μm) or more.

The reinforcing layer may include a dam reinforcing part spaced a predetermined distance apart from the main protective layer and a main reinforcing part disposed between the dam reinforcing part and the sub-protective layer, and an upper dam surface of the dam reinforcing part may include a curved surface having a radius of curvature different from a radius of curvature of an upper main part surface of the main reinforcing part.

The electronic device may further include a sub-reinforcing layer disposed between the reinforcing layer and the main protective layer, and an elastic modulus of the sub-reinforcing layer may be smaller than an elastic modulus of the reinforcing layer.

The elastic modulus of the sub-reinforcing layer may be 100 megapascals (MPa) or less.

The reinforcing layer may be spaced apart from the main protective layer and the sub-protective layer, and a separation distance between the main protective layer and the reinforcing layer may be 50 micrometers (μm) or more.

The electronic device may further include a sub-reinforcing layer disposed between the reinforcing layer and the main protective layer and between the reinforcing layer and the sub-protective layer, and an elastic modulus of the sub-reinforcing layer may be smaller than an elastic modulus of the reinforcing layer.

The display module may include a bending protective part disposed in the bending area, and the electronic device may further include an exterior reinforcing layer spaced apart from the reinforcing layer with the display module interposed therebetween and disposed on the bending protective part.

The electronic device may further include a lower module disposed under the protective layer, and the reinforcing layer may fill 40% or more of an inner space defined by a side surface of the lower module and the bending area.

The electronic device may further include a window disposed on the display module and covering the entire display area, the entire non-display area, and the entire bending area.

According to an embodiment, a method of manufacturing an electronic device includes providing a display module including a display area, a non-display area disposed outside the display area, and a bending area disposed on one side of the non-display area and bent with respect to an imaginary bending axis extending in one direction, providing a protective layer including a main protective layer overlapping the display area and a sub-protective layer spaced apart from the main protective layer and overlapping at least a portion of the bending area, forming a bending protective part on the bending area, providing a reinforcing resin between the main protective layer and the sub-protective layer such that the reinforcing resin is disposed spaced apart from the main protective layer under the display module, temporarily curing the reinforcing resin, bending the bending area such that the temporarily cured reinforcing resin faces an inside, and forming a reinforcing layer by curing the temporarily cured reinforcing resin in a bent state.

The temporarily curing of the reinforcing resin may include controlling flowability of the reinforcing resin by radiating ultraviolet rays to the reinforcing resin.

The forming of the reinforcing layer may include thermally curing the temporarily cured reinforcing resin.

The method may further include, before the providing of the reinforcing resin, providing a dam part reinforcing resin at a location spaced apart from the main protective layer and the sub-protective layer and temporarily curing the dam part reinforcing resin, and the reinforcing resin may be provided between the temporarily reinforced dam part reinforcing resin and the sub-protective layer.

The forming of the reinforcing layer and forming a dam reinforcing part by curing the temporarily cured dam part reinforcing resin may be performed in the same process operation.

The reinforcing resin and the dam part reinforcing resin may include the same material.

The method may further include, after the temporarily curing of the reinforcing resin, providing a sub-reinforcing resin between the temporarily cured reinforcing resin and the main protective layer and temporarily curing the provided sub-reinforcing resin.

The forming of the reinforcing layer and forming a sub-reinforcing layer by curing the temporarily cured sub-reinforcing resin may be performed in the same process operation.

The bending area of the display module may include the bending protective part, and the method may further include, after the forming of the reinforcing layer, providing an exterior reinforcing resin outside the bending protective part and curing the exterior reinforcing resin.

The display module may include a folding display part folded with respect to a folding axis parallel to the bending axis and a first non-folding display part and a second non-folding display part spaced apart from each other with the folding display part interposed therebetween.

### BRIEF DESCRIPTION OF THE FIGURES

The above and other objects and features of the present disclosure will become apparent by describing in detail embodiments thereof with reference to the accompanying drawings.

FIG. 1A is a perspective view illustrating an unfolded state of an electronic device according to an embodiment.

FIG. 1B is a perspective view illustrating an in-folding process of the electronic device according to an embodiment illustrated in FIG. 1A.

FIG. 1C is a perspective view illustrating an out-folding process of the electronic device according to an embodiment illustrated in FIG. 1A.

FIG. 2A is a perspective view illustrating an unfolded state of the electronic device according to an embodiment.

FIG. 2B is a perspective view illustrating an in-folding process of the electronic device according to an embodiment illustrated in FIG. 2A.

FIG. 2C is a perspective view illustrating an out-folding process of the electronic device according to an embodiment illustrated in FIG. 2A.

FIG. 3A is a perspective view of the electronic device according to an embodiment.

FIGS. 3B and 3C are perspective views of the electronic device illustrated in FIG. 3A in a multi-folded state.

FIG. 4 is an exploded perspective view of the electronic device according to an embodiment.

FIG. 5 is a cross-sectional view of a portion of the electronic device according to an embodiment.

FIG. 6 is a cross-sectional view of a portion of the electronic device according to an embodiment.

FIG. 7A is a perspective view of a display module according to an embodiment.

FIG. 7B is a cross-sectional view of a portion of the display module according to an embodiment.

FIG. 8A is a cross-sectional view illustrating a state in which a portion of the electronic device is unfolded according to an embodiment.

FIG. 8B is a cross-sectional view of a portion of the electronic device according to an embodiment.

FIG. 9A is a cross-sectional view illustrating a state in which a portion of the electronic device is unfolded according to an embodiment.

FIG. 9B is a cross-sectional view of a part of the electronic device according to an embodiment.

FIGS. 10A to 10C are cross-sectional views illustrating a state in which a portion of the electronic device is unfolded according to an embodiment.

FIG. 11A is a view exemplarily illustrating a degree of deformation during a folding operation of the electronic device according to an embodiment.

FIG. 11B is a graph depicting a deformation rate during the folding operation of the electronic device according to an embodiment.

FIG. 12 is a flowchart illustrating a method of manufacturing an electronic device according to an embodiment.

FIGS. 13A to 13D are views illustrating operations of the method of manufacturing an electronic device according to an embodiment.

FIG. 14 is a view illustrating an operation of the method of manufacturing an electronic device according to an embodiment.

FIG. 15 is a flowchart of a portion of the method of manufacturing an electronic device according to an embodiment.

FIGS. 16A and 16B are views illustrating operations of the method of manufacturing an electronic device according to an embodiment.

FIG. 17 is a flowchart of a portion of the method of manufacturing an electronic device according to an embodiment.

FIGS. 18A to 18B are views illustrating operations of the method of manufacturing an electronic device according to an embodiment.

FIG. 19 is a flowchart of a portion of the method of manufacturing an electronic device according to an embodiment.

FIG. 20 is a view illustrating an operation of the method of manufacturing an electronic device according to an embodiment.

### DETAILED DESCRIPTION

Since the present disclosure is variously modified and has various forms, an embodiment thereof will be illustrated in the drawings and will be described herein in detail. However, it should be understood that the present disclosure is not limited to a specific disclosure and includes all changes, equivalents, and substitutes included in the spirit and scope of the present disclosure.

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The term “and/or” includes all combinations of one or more components that may be defined by associated components.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

In the specification, the wording “directly disposed” may mean that there is no layer, no film, no area, no plate, and the like added between a part such as a layer, a film, an area, and a plate, and other parts. For example, the wording “directly disposed” may mean that a component is disposed between two layers or two members without using an additional member such as an adhesive member.

Meanwhile, in the specification, the wording “an area/part corresponds to an area/part” means that “an area/part and an area/part overlap each other” and is not limited to a state in which the area/part and the area/part have the same area and/or the same shape. Further, in the specification, the wording “the area/part and the area/part overlap each other” includes a case in which the area/part and the area/part overlap each other on a plane and a designated area/part and a designated area/part at least partially overlap each other on a plane.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, an electronic device according to an embodiment and a method of manufacturing an electronic device according to an embodiment will be described with reference to the accompanying drawings.

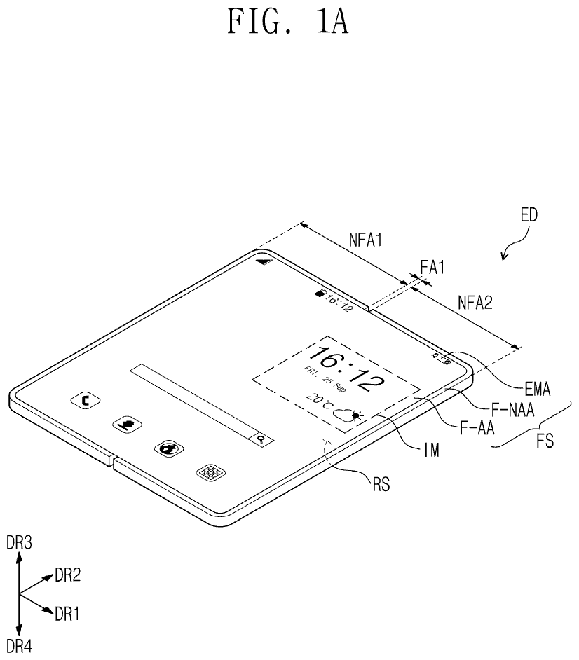

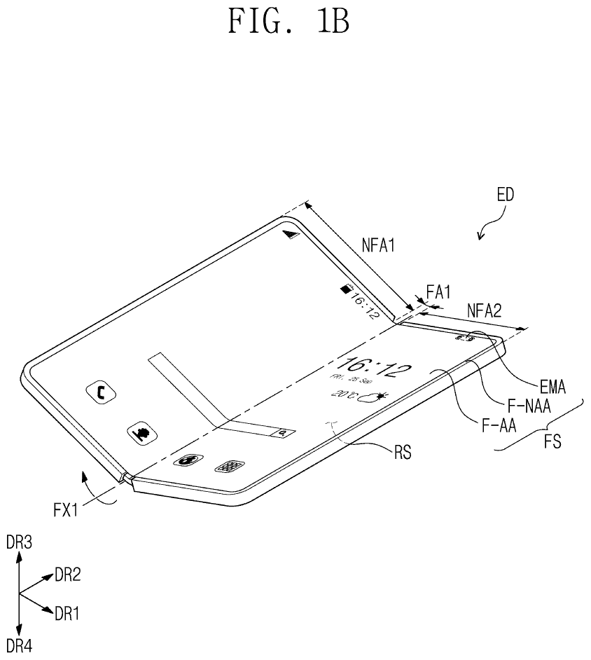

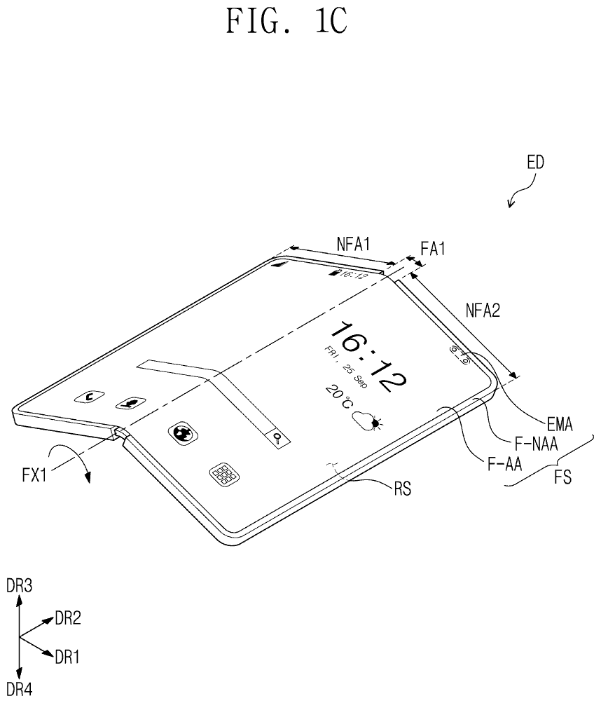

FIG. 1A is a perspective view illustrating an unfolded state of an electronic device according to an embodiment. FIG. 1B is a perspective view illustrating an in-folding process of the electronic device illustrated in FIG. 1A. FIG. 1C is a perspective view illustrating an out-folding process of the electronic device illustrated in FIG. 1A.

An electronic device ED according to an embodiment may be a device that is activated by an electrical signal. For example, the electronic device ED may be a mobile phone, a tablet computer, a vehicle navigation system, a game console, or a wearable device, but an embodiment is not limited thereto. In the specification, FIG. 1A exemplarily illustrates that the electronic device ED is a mobile phone.

Referring to FIGS. 1A to 1C, the electronic device ED according to an embodiment may include a first display surface FS defined by a first directional axis DR1 and a second directional axis DR2 intersecting the first directional axis DR1. The electronic device ED may provide an image IM to a user through the first display surface FS. The electronic device ED according to an embodiment may display the image IM in a third directional axis DR3 to the first display surface FS parallel to the first directional axis DR1 and the second directional axis DR2. In the specification, front surfaces (or upper surfaces) and rear surfaces (or lower surfaces) of components are defined with respect to a direction in which the image IM is displayed. The front surface and the rear surface are opposite to each other in the third directional axis DR3, and a normal direction of each of the front surface and the rear surface may be parallel to the third directional axis DR3.

The electronic device ED according to an embodiment may include the first display surface FS and a second display surface RS. The first display surface FS may include an active area F-AA and a peripheral area F-NAA. The active area F-AA may include an electronic module area EMA. The second display surface RS may be defined as a surface facing at least a portion of the first display surface FS. That is, the second display surface RS may be defined as a portion of the rear surface of the electronic device ED.

The electronic device ED according to an embodiment may sense an external input applied from the outside. The external input may include various types of inputs provided from the outside of the electronic device ED. For example, the external input may include a contact by a part of a body of the user such as a hand as well as an external input (for example, hovering) applied close to the electronic device ED or adjacent to the electronic device ED at a predetermined distance. Further, the external input may have various forms such as a force, a pressure, a temperature, and a light.

FIG. 1A and the following drawings illustrate the first directional axis DR1, the second directional axis DR2, the third directional axis DR3, and a fourth directional axis DR4, and directions indicated by the first directional axis DR1, the second directional axis DR2, the third directional axis DR3, and the fourth directional axis DR4 described in the specification are relative concepts and may be changed to other directions. Further, the directions indicated by the first directional axis DR1, the second directional axis DR2, the third directional axis DR3, and the fourth directional axis DR4 may be described as a first direction DR1, a second direction DR2, a third direction DR3, and a fourth direction DR4, and the same reference numerals may be used therefor. In the specification, the first directional axis DR1 and the second directional axis DR2 may be perpendicular to each other, and the third directional axis DR3 and the fourth directional axis DR4 may be normal directions with respect to a plane defined by the first directional axis DR1 and the second directional axis DR2.

A thickness direction of the electronic device ED may be a direction parallel to the third directional axis DR3 that is a normal direction with respect to the plane defined by the first directional axis DR1 and the second directional axis DR2. The electronic device ED may provide the image IM to the user through a display surface. In the specification, front surfaces (or upper surfaces) and rear surfaces (or lower surfaces) of components are defined with respect to the direction in which the image IM is displayed. In the specification, a direction in which the image IM is displayed may be defined as the third directional axis DR3, and the fourth directional axis DR4 may be defined as a direction opposite to the third directional axis DR3.

In the specification, the wording “on a plane” may be defined as a state of being viewed from the third direction DR3. Meanwhile, the directions indicated by the first direction DR1, the second direction DR2, the third direction DR3, and the fourth direction DR4 may be relative concepts and may be changed to other directions.

The active area F-AA of the electronic device ED may be an area that is activated according to an electrical signal. The electronic device ED according to an embodiment may display the image IM through the active area F-AA. Further, various types of external inputs may be sensed in the active area F-AA. The peripheral area F-NAA is adjacent to the active area F-AA. The peripheral area F-NAA may have a predetermined color. The peripheral area F-NAA may surround the active area F-AA. Accordingly, a shape of the active area F-AA may be substantially defined by the peripheral area F-NAA. However, this is exemplarily illustrated, and the peripheral area F-NAA may be disposed adjacent to only one side of the active area F-AA or may be omitted. The electronic device ED according to an embodiment of the present disclosure may include active areas having various shapes and is not limited to an embodiment.

The electronic device ED may include a folding area FA1 and non-folding areas NFA1 and NFA2. In an embodiment, the non-folding areas NFA1 and NFA2 may be arranged adjacent to the folding area FA1 with the folding area FA1 interposed therebetween. The electronic device ED according to an embodiment may include the first non-folding area NFA1 and the second non-folding area NFA2 spaced apart from each other in the first directional axis DR1 with the folding area FA1 interposed therebetween. For example, the first non-folding area NFA1 may be disposed on one side of the folding area FA1 in the first direction DR1, and the second non-folding area NFA2 may be disposed on the other side of the folding area FA1 in the first direction DR1.

FIGS. 1A to 1C illustrate an embodiment of the electronic device ED including one folding area FA1, but an embodiment is not limited thereto, and a plurality of folding areas may be defined in the electronic device ED. For example, the electronic device according to an embodiment may include two or more folding areas and may include three or more non-folding areas arranged with the folding areas interposed therebetween.

Referring to FIG. 1B, the electronic device ED according to an embodiment may be folded with respect to a first folding axis FX1. The first folding axis FX1 may be an imaginary axis extending in the second directional axis DR2, and the first folding axis FX1 may be parallel to a long side direction of the electronic device ED. The first folding axis FX1 may extend in the second directional axis DR2 on the first display surface FS.

The electronic device ED may be folded with respect to the first folding axis FX1 and may be transformed into an in-folded state in which one area of the first display surface FS overlapping the first non-folding area NFA1 and the other area thereof overlapping the second non-folding area NFA2 face each other.

In the electronic device ED according to an embodiment, the second display surface RS may be visually recognized by the user in the in-folded state. The second display surface RS may further include an electronic module area EMA in which an electronic module including various components is disposed, and is not limited to an embodiment.

Referring to FIG. 1C, the electronic device ED according to an embodiment may be folded with respect to the first folding axis FX1 and may be transformed into an out-folded state in which one area of the second display surface RS overlapping the first non-folding area NFA1 and the other area thereof overlapping the second non-folding area NFA2 face each other.

However, an embodiment is not limited thereto, and the electronic device ED may be folded with respect to a plurality of folding axes so that portions of the first display surface FS and the second display surface RS face each other, and the number of folding axes and the number of non-folding areas are not particularly limited.

Various electronic modules may be arranged in the electronic module area EMA. For example, the electronic module may include at least one of a camera, a speaker, a light sensing sensor, and a heat sensing sensor. The electronic module area EMA may sense an external subject received through the first display surface FS or the second display surface RS or provide a sound signal such as a voice to the outside through the first display surface FS or the second display surface RS. The electronic module may include a plurality of components, and the present disclosure is not limited to an embodiment.

The electronic module area EMA may be surrounded by the active area F-AA and the peripheral area F-NAA. However, the present disclosure is not limited thereto, the electronic module area EMA may be disposed in the active area F-AA, and the present disclosure is not limited to an embodiment.

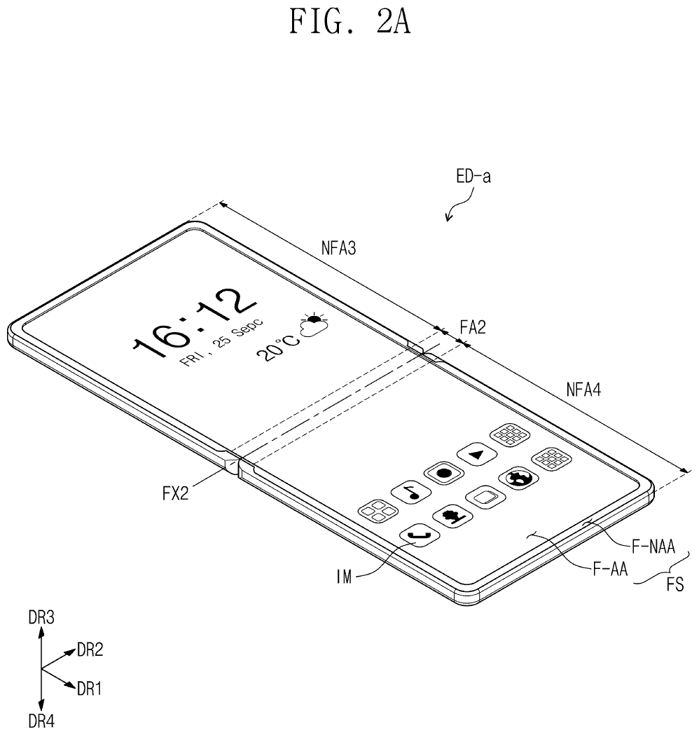

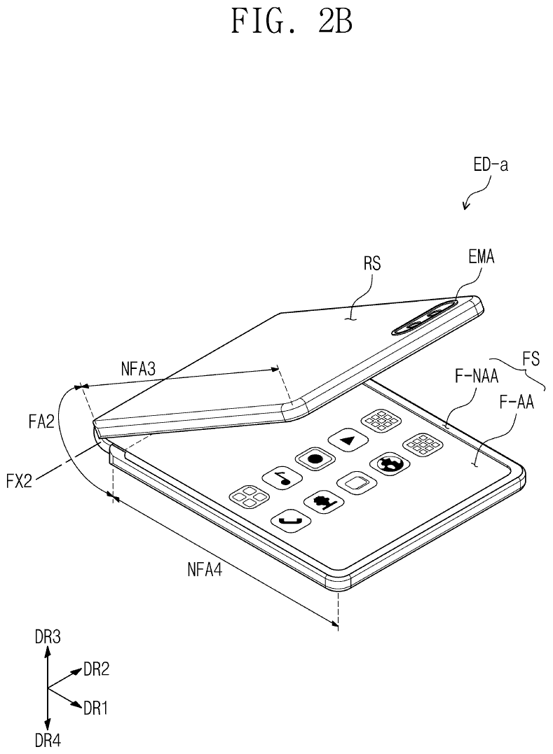

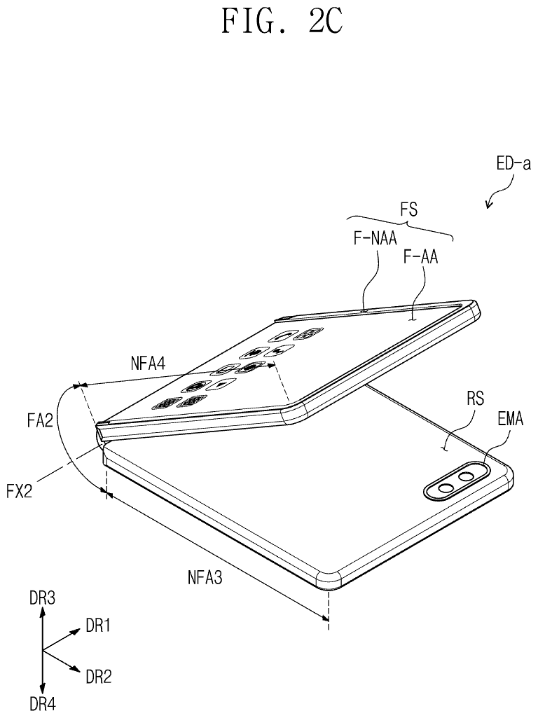

FIG. 2A is a perspective view illustrating an unfolded state of the electronic device according to an embodiment. FIG. 2B is a perspective view illustrating an in-folding process of the electronic device illustrated in FIG. 2A. FIG. 2C is a perspective view illustrating an out-folding process of the electronic device illustrated in FIG. 2A.

An electronic device ED-a according to an embodiment may be folded with respect to a second folding axis FX2 extending in one direction parallel to the second directional axis DR2. FIG. 2B illustrates a case in which an extension direction of the second folding axis FX2 is parallel to an extension direction of a short side of the electronic device ED-a. However, an embodiment is not limited thereto.

The electronic device ED-a according to an embodiment may include at least one folding area FA2 and non-folding areas NFA3 and NFA4 adjacent to the folding area FA2. The non-folding areas NFA3 and NFA4 may be spaced apart from each other with the folding area FA2 interposed therebetween.

The folding area FA2 has a predetermined curvature and a predetermined radius of curvature. In an embodiment, the first non-folding area NFA3 and the second non-folding area NFA4 may face each other, and the electronic device ED-a may be in-folded to prevent the first display surface FS from being exposed to the outside. Further, referring to FIG. 2C, in an embodiment, the electronic device ED-a may be out-folded so that the first display surface FS is exposed to the outside.

The electronic device ED-a according to an embodiment may include the second display surface RS, and the second display surface RS may be defined as a surface facing at least a portion of the first display surface FS. The second display surface RS may include the electronic module area EMA in which the electronic module including various components is disposed. Further, an image may be displayed on at least a portion of the second display surface RS.

In an embodiment, in the electronic device ED-a, the first display surface FS may be visually recognized by the user in a non-folded state, and the second display surface RS may be visually recognized by the user in the in-folded state.

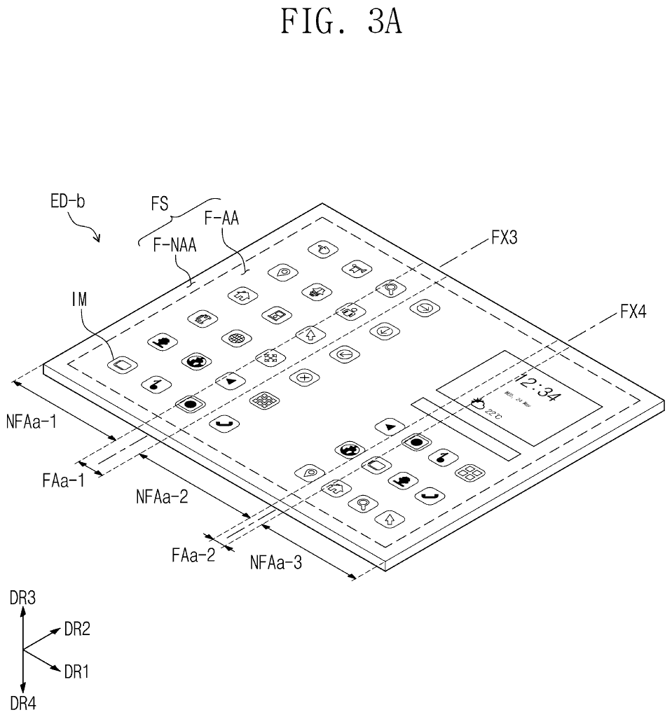

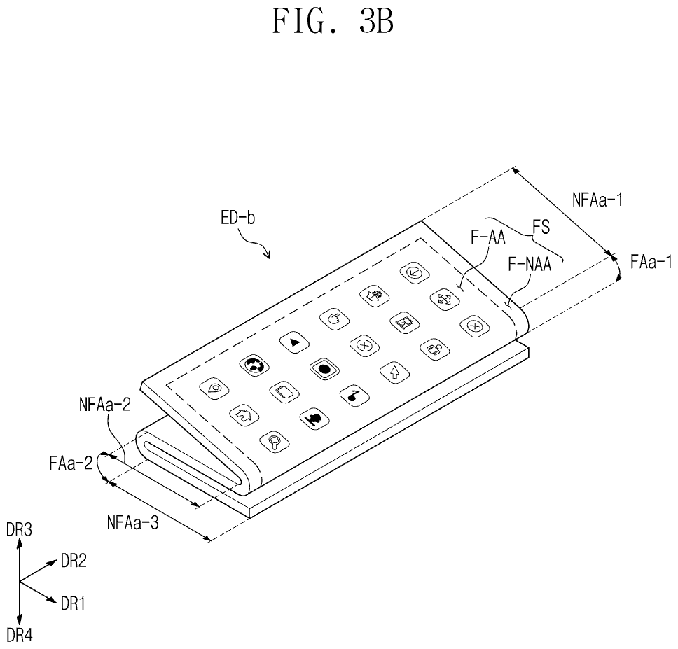

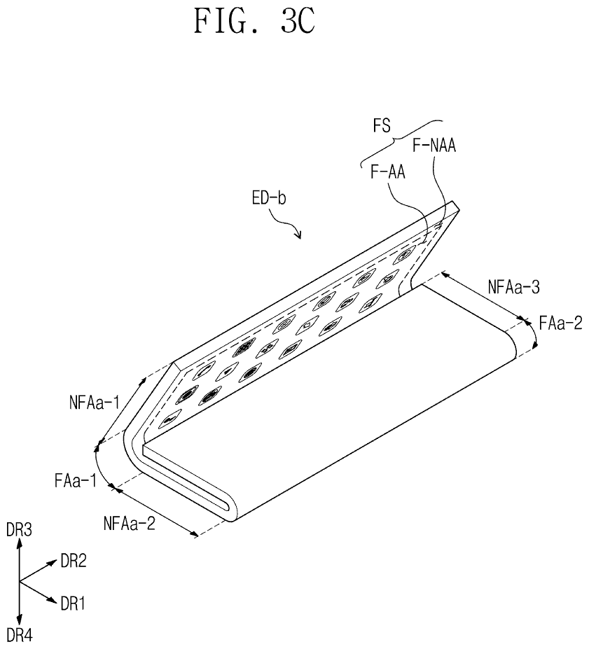

FIG. 3A is a perspective view illustrating an unfolded state of an electronic device ED-b according to an embodiment. FIGS. 3B and 3C are perspective views of the electronic device ED-b illustrated in FIG. 3A in a multi-folded state.

Referring to FIGS. 3A to 3C, the electronic device ED-b according to an embodiment may be a multi-foldable device including the plurality of folding areas. The electronic device ED-b may include a plurality of folding areas FAa-1 and FAa-2, and a plurality of non-folding areas NFAa-1, NFAa-2, and NFAa-3. The electronic device ED-b according to an embodiment may include the first folding area FAa-1, the second folding area FAa-2, the first non-folding area NFAa-1, the second non-folding area NFAa-2, and the third non-folding area NFAa-3. In the first direction DR1, the first folding area FAa-1 is disposed between the first non-folding area NFAa-1 and the second non-folding area NFAa-2, and the second folding area FAa-2 is disposed between the second non-folding area NFAa-2 and the third non-folding area NFAa-3. FIGS. 3A to 3C exemplarily illustrate the two folding areas FAa-1 and FAa-2 and the three non-folding areas NFAa-1, NFAa-2, and NFAa-3, but the numbers of folding areas FAa-1 and FAa-2 and non-folding areas NFAa-1, NFAa-2, and NFAa-3 are not limited thereto and may further increase.

Referring to FIGS. 3A and 3B, the first folding area FAa-1 may be folded with respect to a third folding axis FX3 parallel to the second direction DR2. The first folding area FAa-1 may be out-folded such that a rear surface of the second non-folding area NFAa-2 and a rear surface of the first non-folding area NFAa-1 face each other, and a display surface of the first non-folding area NFAa-1 faces the outside. The second folding area FAa-2 may be folded with respect to a fourth folding axis FX4 parallel to the second direction DR2. The second folding area FAa-2 may be in-folded such that a display surface of the second non-folding area NFAa-2 and a display surface of the third non-folding area NFAa-3 face each other.

Referring to FIGS. 3A and 3C, the second folding area FAa-2 may be folded with respect to the fourth folding axis FX4 parallel to the second direction DR2. The electronic device ED-b may be in-folded such that the display surface of the second non-folding area NFAa-2 is disposed thereinside, and the display surface of the third non-folding area NFAa-3 faces the display surface of the second non-folding area NFAa-2. The first folding area FAa-1 may be folded with respect to the third folding axis FX3 parallel to the second direction DR2. The electronic device ED-b may be in-folded such that a rear surface of the third non-folding area NFAa-3 and the display surface of the first non-folding area NFAa-1 face each other.

However, the multi-folded state is not limited to the forms illustrated in FIGS. 3B and 3C and may have various folding forms.

In an embodiment of the present disclosure, an out-folding operation and an in-folding operation may occur at the same time, and only one of the out-folding operation and the in-folding operation may occur.

In an embodiment, the electronic devices ED, ED-a, and ED-b may be configured such that the in-folding operation or the out-folding operation are repeated from an unfolding operation, but an embodiment is not limited thereto. In an embodiment, the electronic devices ED, ED-a, and ED-b may be configured to select any one of the unfolding operation, the in-folding operation, and the out-folding operation. Further, when the plurality of folding areas are included, a folding direction of at least one of the plurality of folding areas may be different from a folding direction of the other folding areas. For example, when two folding areas are included, two non-folding areas between one folding area may be folded in the in-folding operation, and two non-folding areas between the other one folding area may be folded in the out-folding operation.

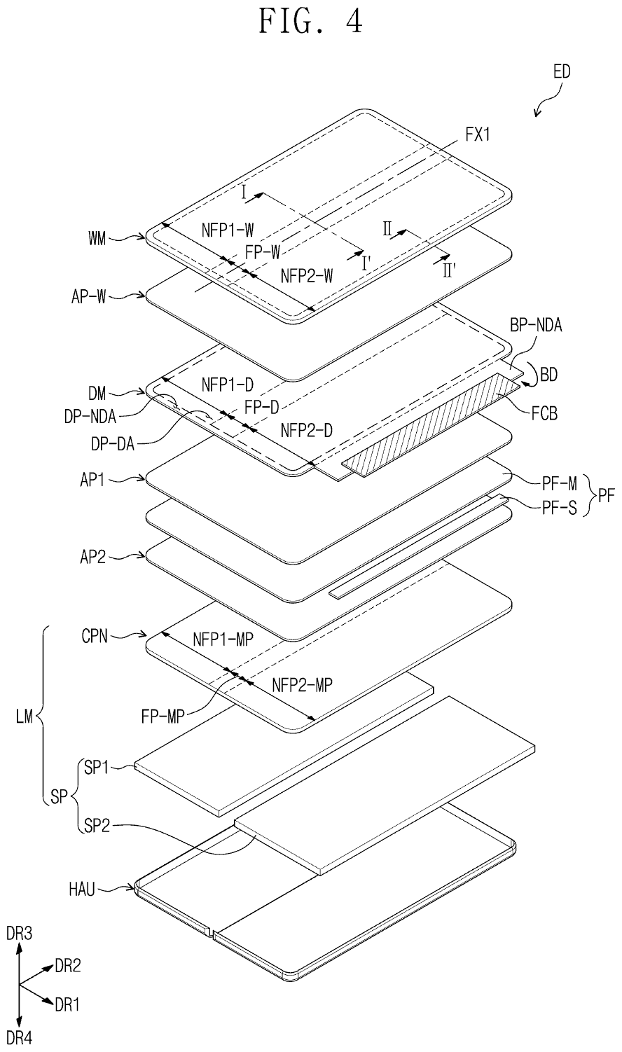

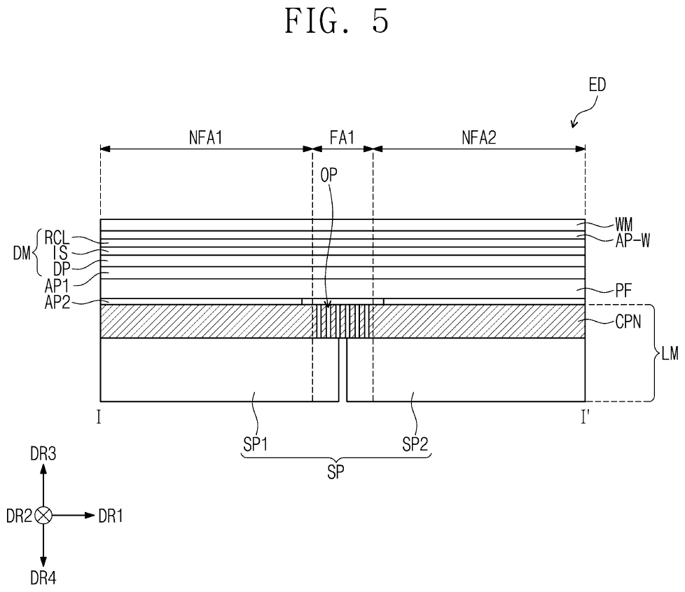

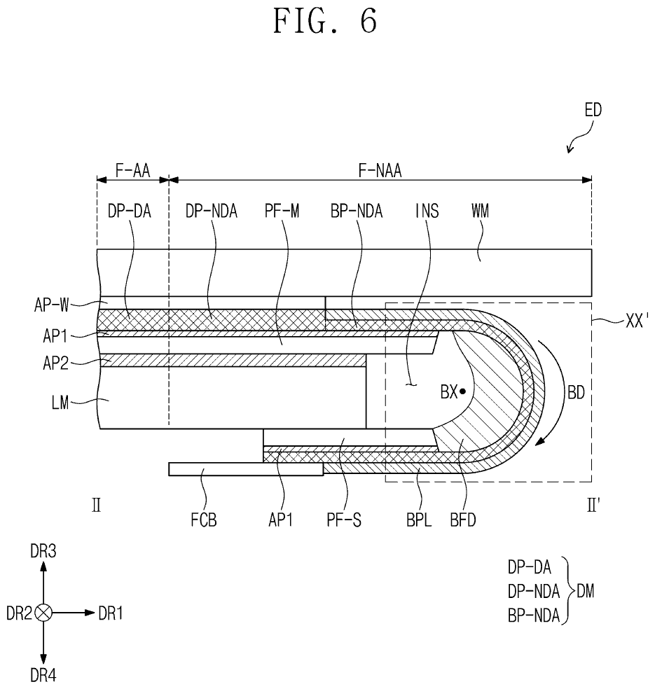

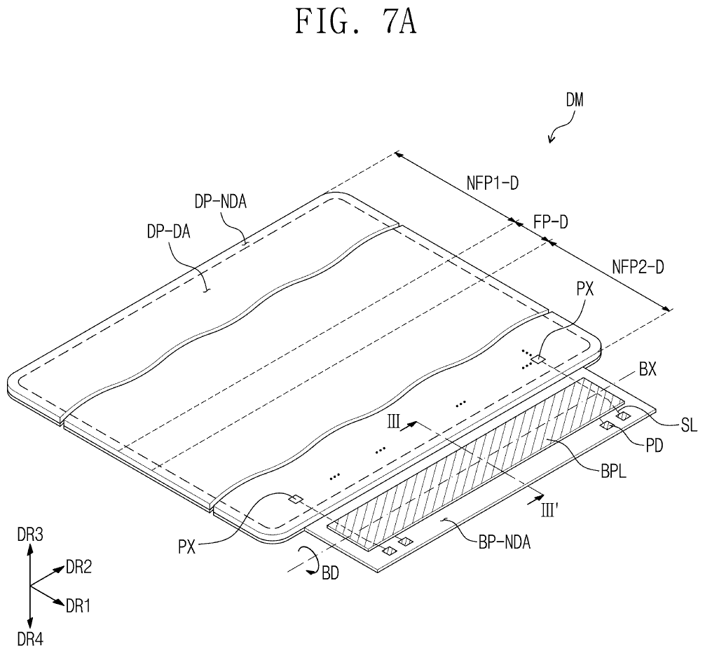

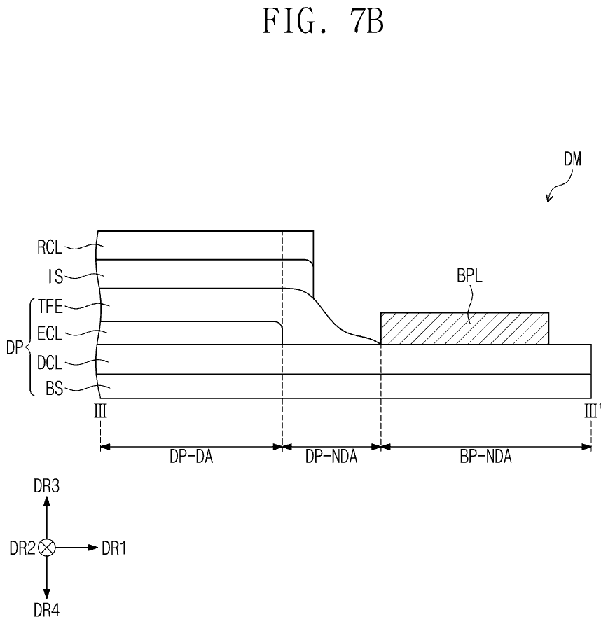

FIG. 4 is an exploded perspective view of an electronic device according to an embodiment. FIGS. 5 and 6 are cross-sectional views of a portion of the electronic device according to an embodiment. FIG. 4 is an exploded perspective view exemplarily illustrating the electronic device according to an embodiment illustrated in FIG. 1A. FIG. 5 is a cross-sectional view illustrating a portion corresponding to line I-I′ of FIG. 4, and FIG. 6 is a cross-sectional view illustrating a portion corresponding to line II-II′ of FIG. 4. FIG. 7A is a perspective view of a display module according to an embodiment, and FIG. 7B is a cross-sectional view of the display module according to an embodiment. FIG. 7B is a cross-sectional view of a portion corresponding to line III-III′ of FIG. 7A.

Hereinafter, FIG. 4 and the like illustrate a case in which the first folding axis FX1 of the electronic device ED illustrated in FIG. 1A or the like is parallel to the long side of the electronic device ED, but an embodiment is not limited thereto, and the following contents described with reference to the accompanying drawings may be applied to a case in which the second folding axis FX2 is parallel to the short side of the electronic device as illustrated in FIG. 2A or the like or to the multi-folded electronic device as illustrated in FIG. 3A or the like.

Referring to FIGS. 4 to 6, the electronic device ED according to an embodiment may include a display module DM, a window WM disposed on the display module DM, a protective layer PF disposed under the display module DM, and a reinforcing layer BFD disposed under the display module DM. Further, the electronic device ED according to an embodiment may include a circuit board FCB electrically connected to the display module DM.

The electronic device ED according to an embodiment may further include a lower module LM disposed under the display module DM. The lower module LM may be referred to as a support member. Further, the electronic device ED according to an embodiment may further include at least one adhesive layer AP-W, AP1, and AP2.

The electronic device ED may include a housing HAU accommodating the display module DM and the lower module LM. The housing HAU may be coupled to the window WM. Although not illustrated, the housing HAU may further include a hinge structure for facilitating folding or bending. In FIGS. 5 and 6, the housing HAU is omitted.

In the electronic device ED according to an embodiment, the window WM may cover the entire upper surface of the display module DM. The window WM may have a shape corresponding to a shape of the display module DM. The window WM may include a glass substrate and may be used as a cover window of the electronic device.

The glass substrate included in the window WM may be a reinforced glass substrate. Further, the glass substrate may be an ultra-thin reinforced glass substrate. The window WM may further include a protective film disposed on the glass substrate. The protective film may be disposed on the window WM to protect the window WM from an external environment.

The window WM may include a folding part FP-W and non-folding parts NFP1-W and NFP2-W. The first non-folding part NFP1-W and the second non-folding part NFP2-W of the window WM may be spaced apart from each other in the first direction DR1 with the folding part FP-W interposed therebetween. The folding part FP-W may be a part corresponding to the folding area FA1, and the non-folding parts NFP1-W and NFP2-W may be parts corresponding to the non-folding areas NFA1 and NFA2.

The lower module LM may include a support plate CPN. The support plate CPN may include a folding support part FP-MP and non-folding support parts NFP1-MP and NFP2-MP. The first non-folding support part NFP1-MP and the second non-folding support part NFP2-MP of the support plate CPN may be spaced apart from each other with the folding support part FP-MP interposed therebetween. The folding support part FP-MP may be a part corresponding to the folding area FA1 (see FIG. 1A), and the non-folding support parts NFP1-MP and NFP2-MP may be parts corresponding to the non-folding areas NFA1 and NFA2 (see FIG. 1A). A plurality of openings OP may be defined in the support plate CPN. The openings OP may be defined to correspond to the folding area FA1.

The lower module LM may further include a support module SP disposed under the support plate CPN. The support module SP may include support layers SP1 and SP2. The support layers SP1 and SP2 may include the first support layer SP1 and the second support layer SP2 spaced apart from each other in the first directional axis DR1. The first support layer SP1 and the second support layer SP2 may be spaced apart from each other at a portion corresponding to the first folding axis FX1 (see FIGS. 1B and 1C). The support layers SP1 and SP2 may be spaced apart from each other in the folding area FA1 and provided as the first support layer SP1 and the second support layer SP2, thereby improving folding or bending characteristics of the electronic device ED.

Although not illustrated, the lower module LM may further include a cushion layer, an additional lower support plate, a digitizer, and a shielding layer that are laminated in a thickness direction in addition to the support plate CPN and the support module SP. In the electronic device ED according to an embodiment, a combination of the components included in the lower module LM may be changed depending on a size and shape of the electronic device ED, or operating characteristics of the electronic device ED.

The display module DM may be disposed between the window WM and the lower module LM. The display module DM may display an image according to an electrical signal and transmit/receive information on an external input.

The display module DM may include a folding display part FP-D and non-folding display parts NFP1-D and NFP2-D. The folding display part FP-D may be a part corresponding to the folding area FA1 (see FIG. 1A), and the non-folding display parts NFP1-D and NFP2-D may be parts corresponding to the non-folding areas NFA1 and NFA2 (see FIG. 1A).

The folding display part FP-D may correspond to a part that is folded or bent with respect to the first folding axis FX1 (see FIGS. 1B and 1C). The display module DM may include the first non-folding display part NFP1-D and the second non-folding display part NFP2-D, and the first non-folding display part NFP1-D and the second non-folding display part NFP2-D may be spaced apart from each other with the folding display part FP-D interposed therebetween.

Referring to FIGS. 4 to 7B, the display module DM may include a display area DP-DA, a non-display area DP-NDA, and a bending area BP-NDA. The bending area BP-NDA may be referred to as a non-display bending part.

The display area DP-DA may be defined as an area that emits an image provided from the display module DM. Further, the display area DP-DA may function as a sensing area for sensing an external input. According to an embodiment, the display area DP-DA of the display module DM may correspond to at least a portion of the active area F-AA (see FIG. 1A). A plurality of pixel areas PX may be arranged in the display area DP-DA. Each of the pixel areas PX may be controlled to emit a light for image emission. Each of the pixel areas PX may be referred to as a light emitting area that is operated by an electrical signal to emit a light.

The non-display area DP-NDA is adjacent to the display area DP-DA. For example, the non-display area DP-NDA may surround the display area DP-DA outside the display area DP-DA. However, this is exemplarily illustrated, the non-display area DP-NDA may be defined in various shapes, and the present disclosure is not limited to an embodiment.

The display module DM may include the bending area BP-NDA disposed on at least one side of the non-display area DP-NDA. The bending area BP-NDA may be bent (marked as “BD” in figures) with respect to an imaginary bending axis BX extending in one direction (e.g., second direction DR2) and accommodated in the housing HAU. The bending area BP-NDA may be bent (BD) in the fourth direction DR4 with respect to the bending axis BX, and the bending area BP-NDA may overlap a portion of the non-display area DP-NDA in a bent state. Further, the bending area BP-NDA may overlap at least a portion of the display area DP-DA in a bent state. The bending area BP-NDA may be bent to overlap the non-display area DP-NDA or the like adjacent thereto, and thus an area of the peripheral area F-NAA (see FIG. 1A), which is visually recognized on the first display surface FS (see FIG. 1A) of the electronic device ED, may be reduced.

A signal wiring line SL electrically connected to the pixel area PX and the like and a pad PD connected to the signal wiring line SL or the like may be arranged in the bending area BP-NDA. Further, although not illustrated, a circuit wiring line, a driving chip, and the like for controlling an operation of the display module DM may be additionally arranged in the bending area BP-NDA.

The electronic device ED according to an embodiment may be connected to the circuit board FCB or the like in the bending area BP-NDA. The circuit board FCB may be electrically connected to the pad PD or the like disposed in the bending area BP-NDA. After the circuit board FCB is connected to the bending area BP-NDA, the bending area BP-NDA may be bent (BD), and the circuit board FCB may be disposed to overlap the display module DM.

The display module DM according to an embodiment may include a bending protective part BPL. The bending protective part BPL may be disposed in the bending area BP-NDA. The bending protective part BPL may cover the signal wiring line SL or the like disposed in the bending area BP-NDA. The bending protective part BPL may protect components under the signal wiring line SL and the display module DM during a bending operation or in a bent state (BD). While FIG. 7A and the like illustrate that the bending protective part BPL is disposed only in the bending area BP-NDA, but an embodiment is not limited thereto, and the bending protective part BPL may be expanded and disposed to a portion of the non-display area DP-NDA adjacent to the bending area BP-NDA.

The bending protective part BPL may have a modulus characteristic that is not damaged by cracks or the like even after bending. The bending protective part BPL may be formed by providing an organic resin and curing the provided resin.

In an embodiment, the display module DM includes a display panel DP. The display panel DP may be a light emitting display panel, and the present disclosure is not particularly limited. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot and a quantum rod.

The display module DM may further include an input sensor IS. The input sensor IS may be directly disposed on the display panel DP. The input sensor IS may include a plurality of sensing electrodes. The input sensor IS may sense an external input in a self-cap method or a mutual cap method. The input sensor IS may also sense an input by an active type input device.

The input sensor IS may be directly formed on the display panel DP through a continuous process when the display panel DP is manufactured. However, an embodiment is not limited thereto, and the input sensor IS may be manufactured as a separate panel from the display panel DP and attached to the display panel DP by an adhesive layer (not illustrated).

Further, the display module DM may further include an optical layer RCL. The optical layer RCL may function to reduce reflection by an external light. For example, the optical layer RCL may include a polarizing layer or a color filter layer. However, an embodiment is not limited thereto, and the optical layer RCL may include optical members for improving display quality of the electronic device ED.

In an embodiment, the optical layer RCL may be directly disposed on the input sensor IS. Further, when the input sensor IS is omitted from the display module DM, the optical layer RCL may be directly disposed on the display panel DP. However, an embodiment is not limited thereto, and the optical layer RCL may be disposed on the display panel DP or the input sensor IS using a separate adhesive member.

The display panel DP may include a base layer BS, a circuit layer DCL, a display layer ECL, and an encapsulation layer TFE.

In an embodiment, the base layer BS may be a support substrate on which the circuit layer DCL and the display layer ECL are provided. In an embodiment, the base layer BS may be a glass substrate, a metal substrate, a polymer substrate, or the like. However, an embodiment is not limited thereto, and the base layer BS may be an inorganic layer or an organic/inorganic composite material layer. In one embodiment, the base layer BS may have a multi-layer structure. For example, the base layer BS may have a three-layer structure of a polymer resin layer, an adhesive layer, and a polymer resin layer. In particular, the polymer resin layer may include a polyimide-based resin.

The circuit layer DCL is disposed on the base layer BS. The circuit layer DCL may include at least one insulating layer and a plurality of circuit elements formed by providing an insulating layer, a semiconductor layer, a conductive layer, and the like on the base layer BS through coating or deposition and then being patterned through photolithography multiple times. The circuit layer DCL, which is a circuit element, may include a transistor, a signal line, a driving circuit of a pixel, and the like. An insulating layer of the circuit layer DCL may be formed by coating or deposition, and the circuit element may be formed by a photolithography process including providing and patterning of a semiconductor layer or a conductive layer.

The display layer ECL includes a display element. The display element may include a light emitting element that generates and provides a light. For example, the light emitting element may include an organic light emitting material, an inorganic light emitting material, an organic-inorganic light emitting material, a quantum dot, a quantum rod, a micro light emitting diode (LED), or a nano LED. The display element of the display layer ECL may be operated and controlled while electrically connected to the transistor, the signal line, the driving circuit of the pixel of the circuit layer DCL, or the like.

The encapsulation layer TFE may be disposed on the display layer ECL. The encapsulation layer TFE may protect the display layer ECL, that is, a light emitting element, from foreign substances such as moisture, oxygen, and dust particles. The encapsulation layer TFE may include at least one inorganic encapsulation layer. The encapsulation layer TFE may include a laminated structure of a first encapsulation inorganic layer/an encapsulation organic layer/a second encapsulation inorganic layer.

Referring to FIG. 7B, the laminated structures of the display module DM in the display area DP-DA, the non-display area DP-NDA, and the bending area BP-NDA may be different from each other. The display layer ECL may be disposed in the display area DP-DA, and the display layer ECL may not be disposed in the non-display area DP-NDA and the bending area BP-NDA.

In the non-display area DP-NDA, the display layer ECL is not disposed, but the base layer BS and the circuit layer DCL may be arranged, and some of the encapsulation layer TFE, the input sensor IS, and the optical layer RCL may be arranged. Further, the base layer BS and the circuit layer DCL may be arranged in the bending area BP-NDA. The bending area BP-NDA may include the bending protective part BPL, and the bending protective part BPL may be disposed on the circuit layer DCL.

FIG. 7B exemplarily illustrates that configurations of the display area DP-DA, the non-display area DP-NDA, and the bending area BP-NDA in the display module DM may be different from each other, and a laminated structure of the non-display area DP-NDA and the bending area BP-NDA is not limited to the illustration of FIG. 7B.

For example, in an embodiment, a portion of the encapsulation layer TFE may be disposed to extend to the bending area BP-NDA, and in this case, the bending protective part BPL may be disposed on the encapsulation layer TFE. Further, when the encapsulation layer TFE has a structure in which a plurality of layers are laminated, only some of the plurality of layers may extend and be located in the non-display area DP-NDA. Further, configurations of the input sensor IS in the display area DP-DA and the non-display area DP-NDA may be different from each other.

A configuration of the circuit layer DCL in the bending area BP-NDA may be different from a configuration of the circuit layer DCL in the display area DP-DA and the non-display area DP-NDA. Only a portion of a configuration of the circuit layer DCL included in the display area DP-DA may extend to and be included in the bending area BP-NDA. In the bending area BP-NDA, the signal wiring line SL or the like connected to the circuit board FCB (see FIG. 6) may be included in the circuit layer DCL.

Referring to FIGS. 4 to 6, the protective layer PF may be disposed between the display module DM and the support plate CPN. The protective layer PF may be a layer disposed under the display module DM to protect a rear surface of the display module DM. For example, the protective layer PF may be a polyimide film or a polyethylene terephthalate film. However, this is exemplary, and a material of the protective layer PF is not limited thereto.

The protective layer PF may include a main protective layer PF-M that mainly overlaps the display area DP-DA of the display module DM and a sub-protective layer PF-S that is spaced apart from the main protective layer PF-M and disposed to overlap at least a portion of the bending area BP-NDA.

In a state in which the bending area BP-NDA is bent, the main protective layer PF-M and the sub-protective layer PF-S may overlap each other in the third direction DR3. The lower module LM may be disposed between the main protective layer PF-M and the sub-protective layer PF-S, which overlap each other in the third direction DR3.

The electronic device ED according to an embodiment may include the window adhesive layer AP-W disposed between the display module DM and the window WM. The window adhesive layer AP-W may be an optical transparent adhesive film or an optical transparent adhesive resin layer. In another embodiment, the window adhesive layer AP-W may be omitted.

Further, the electronic device ED according to an embodiment may further include the first adhesive layer AP1 disposed between the display module DM and the protective layer PF and the second adhesive layer AP2 disposed between the protective layer PF and the support plate CPN. In another embodiment, the electronic device ED may further include an adhesive layer for additionally coupling the respective members in addition to those illustrated.

The at least one adhesive layer AP-W, AP1, and AP2 may be an optical transparent adhesive film or an optical transparent adhesive resin layer. However, an embodiment is not limited thereto, and the at least one adhesive layer AP-W, AP1, and AP2 may be an adhesive layer having a low transmittance of 80% or less.

In the electronic device ED according to an embodiment, the window WM may be disposed on the display module DM, and the window WM may cover the entire display area DP-DA, the entire non-display area DP-NDA, and the entire bending area BP-NDA. An edge of the window WM may be located outside an edge of the bending protective part BPL disposed in the bending area BP-NDA.

The electronic device ED according to an embodiment may include the reinforcing layer BFD. The reinforcing layer BFD may be disposed in the bending area BP-NDA of the display module DM. The reinforcing layer BFD may be disposed to overlap the display module DM in a portion in which the protective layer PF is not disposed. In a state in which the bending area BP-NDA of the display module DM is bent, the reinforcing layer BFD may also be disposed in a bent state.

Referring to FIG. 6, one surface of the exposed reinforcing layer BFD may have a curvature. However, a curved shape of the reinforcing layer BFD illustrated in FIG. 6 is exemplary, and an exposed upper surface of the reinforcing layer BFD may include a portion protruding convexly toward the lower module LM.

The reinforcing layer BFD may be disposed between the main protective layer PF-M and the sub-protective layer PF-S, and may be spaced apart from the main protective layer PF-M. As the reinforcing layer BFD is spaced a predetermined distance apart from the main protective layer PF-M, when the electronic device ED is deformed due to folding, even when the main protective layer PF-M is stretched according to a numerical change of the main protective layer PF-M and thus a slip phenomenon occurs at a portion thereof, collision between the main protective layer PF-M and the reinforcing layer BFD may be prevented. Accordingly, a stress or the like caused by the collision between the main protective layer PF-M and the reinforcing layer BFD, which may occur when the electronic device ED is folded, may be prevented from being transmitted to components of the display module DM of the display area DP-DA or the bending area BP-NDA.

The reinforcing layer BFD may fill at least a portion of a space defined between the display module DM and the lower module LM while the bending area BP-NDA is bent. The reinforcing layer BFD may fill a portion of an inner bending area INS (e.g., inner space) defined by a side surface of the lower module LM and the bending area BP-NDA of the display module DM. For example, the reinforcing layer BFD may fill 40% or more of the inner bending area INS.

Durability and reliability of the electronic device ED may be improved by the reinforcing layer BFD that is disposed under the display module DM to correspond to the bending area BP-NDA and fills at least a portion of the inner bending area INS. Further, as the reinforcing layer BFD is spaced apart from the main protective layer PF-M, even when the display module DM and other electronic device components slip when the electronic device ED is folded and deformed, a stress caused by the collision with the reinforcing layer BFD may be prevented from being transmitted to the display area DP-DA or the like, and thus the electronic device ED may exhibit excellent operational reliability.

The reinforcing layer BFD may be formed of an organic resin. The reinforcing layer BFD may have a modulus characteristic in which no crack occurs when the reinforcing layer BFD is maintained in a bent state and the display module DM may be protected from an external impact.

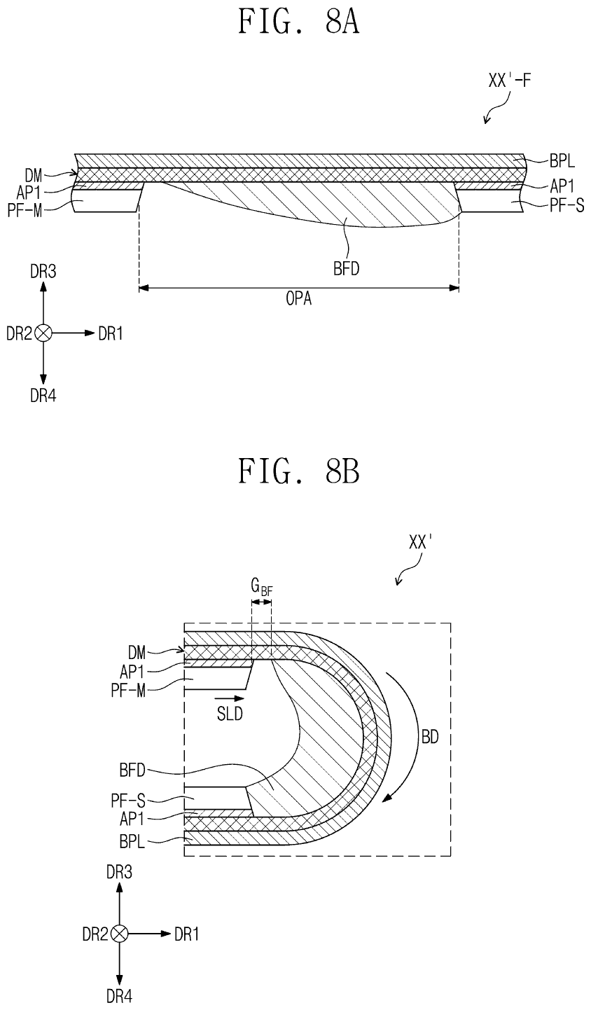

FIGS. 8A and 8B are enlarged views illustrating only components of area XX′ of FIG. 6. FIG. 8A illustrates a state XX′-F in which the area XX′ is unfolded, and FIG. 8B illustrates the area XX′ of the electronic device in a state in which the part illustrated in FIG. 8A is fixedly bent (BD) in the fourth direction DR4.

The reinforcing layer BFD may be disposed in an open area OPA defined between the main protective layer PF-M and the sub-protective layer PF-S. In an embodiment illustrated in FIGS. 8A and 8B, one side of the reinforcing layer BFD may be adjacent to the sub-protective layer PF-S. One exposed surface of the reinforcing layer BFD may be a curved surface, and a thickness of the reinforcing layer BFD in the unfolded state XX′-F may include a portion is decreased toward the main protective layer PF-M.

As illustrated in FIG. 8B, in the electronic device, the reinforcing layer BFD may be bent (BD) and located together with the display module DM in a state in which the reinforcing layer BFD is disposed on one surface of the display module DM.

In an embodiment, a separation distance between the main protective layer PF-M and the reinforcing layer BFD may be adjusted by a folding operation of the electronic device in consideration of a degree of deformation of the display module DM, the main protective layer PF-M, the adhesive layer AP1, and the like. In an embodiment, a separation distance G_{BF} between the main protective layer PF-M and the reinforcing layer BFD in a bent state may be 50 μm or more.

When the separation distance G_{BF} between the main protective layer PF-M and the reinforcing layer BFD in a bent state is 50 μm or more, even when the main protective layer PF-M is deformed in a slip direction SLD, a separation state from the reinforcing layer BFD may be maintained.

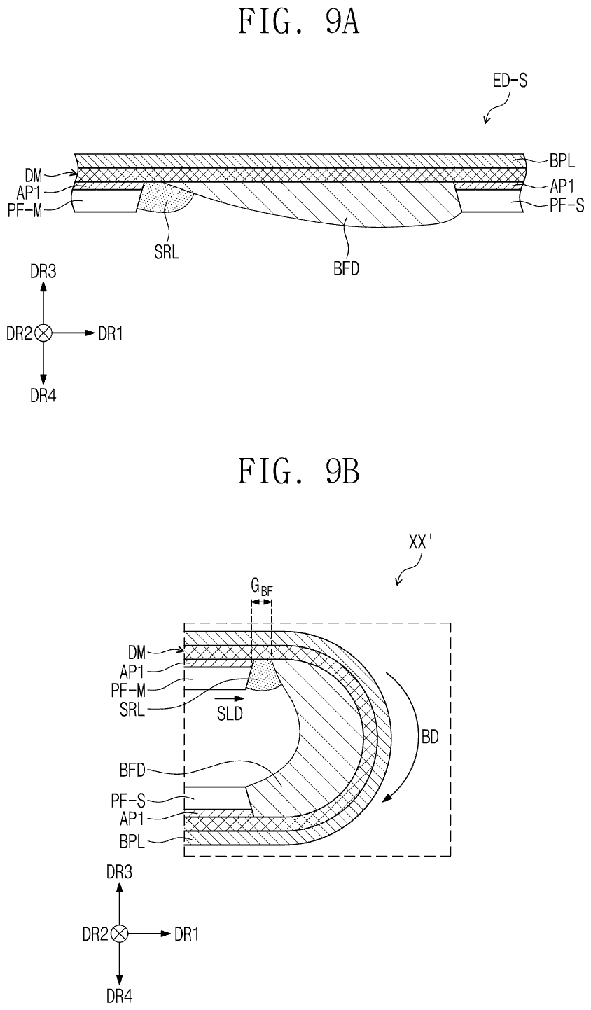

FIGS. 9A and 9B are cross-sectional views of a part of the electronic device according to an embodiment. FIGS. 9A and 9B are enlarged views illustrating only components corresponding to the area XX′ of FIG. 6. An electronic device ED-S according to an embodiment illustrated in FIGS. 9A and 9B is different from the electronic device ED according to an embodiment illustrated in FIGS. 8A and 8B in that the former further includes a sub-reinforcing layer SRL.

The sub-reinforcing layer SRL may be disposed between the reinforcing layer BFD and the main protective layer PF-M. The sub-reinforcing layer SRL may fill a space between the reinforcing layer BFD and the main protective layer PF-M.

The sub-reinforcing layer SRL may have a low elastic modulus compared to the reinforcing layer BFD. The sub-reinforcing layer SRL may have a low elastic modulus characteristic of 100 MPa or less under all a room temperature condition, a high temperature condition, and a low temperature condition. Further, the sub-reinforcing layer SRL may have a low hardness characteristic compared to the reinforcing layer BFD.

In an embodiment, the reinforcing layer BFD and the sub-reinforcing layer SRL may be formed of a silicon-based resin. The reinforcing layer BFD and the sub-reinforcing layer SRL may be formed by UV-curing the provided silicone-based resin. For example, the reinforcing layer BFD may have an elastic modulus value of about 1050 MPa at the room temperature (25° C.), and in comparison, the sub-reinforcing layer SRL may have an elastic modulus value of about 0.018 MPa at the room temperature. Further, the sub-reinforcing layer SRL may have an elastic modulus value of about 20 MPa at a low temperature (−20° C.). In an embodiment, the reinforcing layer BFD may have a Shore hardness of about 70, and in comparison, the sub-reinforcing layer SRL may have a Shore hardness of about 30. However, an embodiment is not limited thereto. Even when the main protective layer PF-M or the like is deformed due to a slip phenomenon, the sub-reinforcing layer SRL may sufficiently absorb a stress to prevent a stress from being transmitted to the reinforcing layer BFD. Further, as the sub-reinforcing layer SRL has a low modulus property, even when a stress is applied to the bending area BP-NDA from an outside of an electronic device ED-S, the sub-reinforcing layer SRL may sufficiently absorb the stress transmitted from the reinforcing layer BFD to prevent the stress from being transmitted to the main protective layer PF-M and the display area DP-DA of the display module DM.

For example, the sub-reinforcing layer SRL may exhibit a low modulus characteristic similar to the modulus characteristic of a pressure-sensitive adhesive layer. Accordingly, the electronic device ED-S may be deformed by an external force, and thereafter, even when the external force is removed, deformation of components of the electronic device ED-S may be minimized by an excellent restoring force. That is, as the sub-reinforcing layer SRL has a low elastic modulus characteristic, even when a slip phenomenon occurs in the main protective layer PF-M while the electronic device is transformed into a folding state and an unfolding state, the sub-reinforcing layer SRL may absorb deformation caused by the deformation of the main protective layer PF-M to prevent a deformation stress from being transmitted to the reinforcing layer BFD.

Further, the sub-reinforcing layer SRL may have an electrostatic shielding property. Because the sub-reinforcing layer SRL has an electrostatic shielding function in addition to shock absorption and excellent restoration, electrical reliability of the display module DM and the like may be further improved.

In an embodiment illustrated in FIGS. 9A and 9B, one side of the reinforcing layer BFD may be adjacent to the sub-protective layer PF-S. Further, the other side of the reinforcing layer BFD may be adjacent to the sub-reinforcing layer SRL.

In an embodiment, the separation distance between the main protective layer PF-M and the reinforcing layer BFD may be adjusted by the folding operation of the electronic device in consideration of the degree of deformation of the display module DM, the main protective layer PF-M, the adhesive layer AP1, and the like. In an embodiment in which the sub-reinforcing layer SRL is filled between the main protective layer PF-M and the reinforcing layer BFD, the separation distance G_{BF} between the main protective layer PF-M and the reinforcing layer BFD in a bent state may be 50 μm or more.

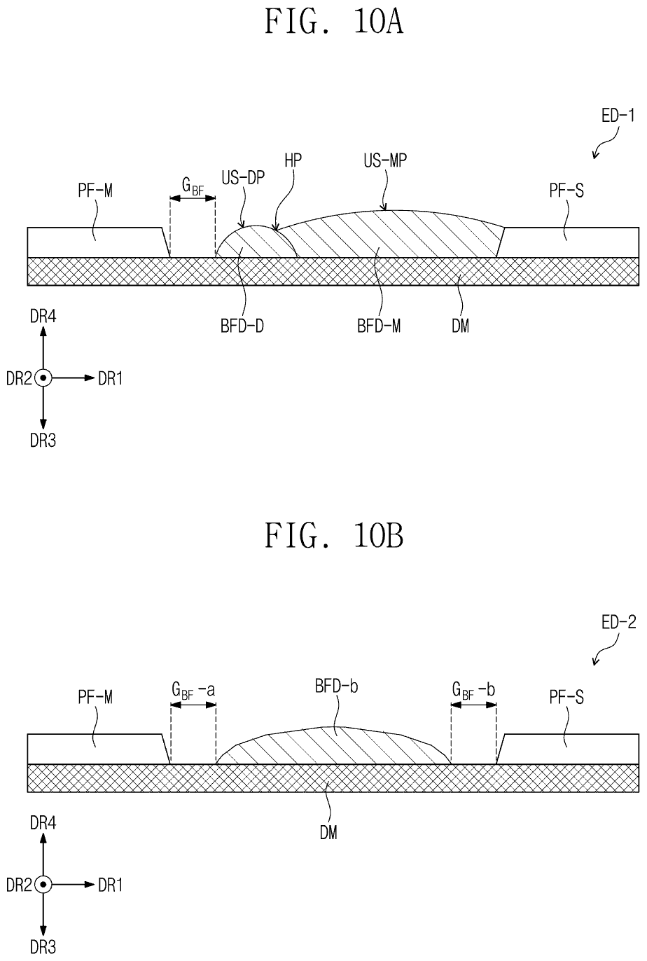

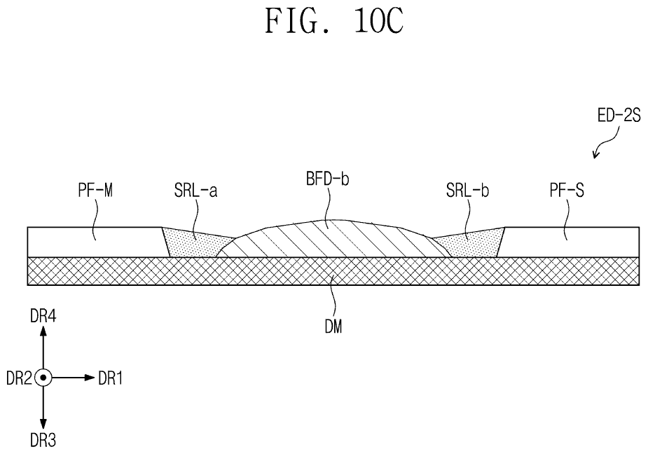

FIGS. 10A to 10C are cross-sectional views of a partial area of the electronic device according to an embodiment. FIGS. 10A to 10C illustrate parts corresponding to the area XX′ of FIG. 6 and briefly illustrate some components in a state in which the area XX′ is unfolded.

Referring to FIG. 10A, an electronic device ED-1 according to an embodiment may include a dam reinforcing part BFD-D and a main reinforcing part BFD-M arranged between the main protective layer PF-M and the sub-protective layer PF-S.

An upper dam surface US-DP of the dam reinforcing part BFD-D and an upper main part surface US-MP of the main reinforcing part BFD-M may include curved surfaces having different radii of curvature. For example, a radius of curvature of the curved surface defining the upper dam surface US-DP and a radius of curvature of the curved surface defining the upper main part surface US-MP may be different from each other. A bent part HP of which a radius of curvature is changed may be located between the upper dam surface US-DP of the dam reinforcing part BFD-D and the upper main part surface US-MP of the main reinforcing part BFD-M. The bent part HP may be formed because the dam reinforcing part BFD-D and the main reinforcing part BFD-M are formed by providing and curing a reinforcing resin in different processes.

FIG. 10A illustrates that the dam reinforcing part BFD-D and the main reinforcing part BFD-M are separated with a boundary, but an embodiment is not limited thereto. In an embodiment, the dam reinforcing part BFD-D and the main reinforcing part BFD-M may be recognized as an integral shape in which a boundary therebetween is not divided. However, even in this case, the bent part HP of which the radius of curvature is changed may be located between the upper dam surface US-DP of the dam reinforcing part BFD-D and the upper main part surface US-MP of the main reinforcing part BFD-M.

In an embodiment illustrated in FIG. 10A, the dam reinforcing part BFD-D and the main protective layer PF-M may be spaced a predetermined distance apart from each other. Although an unfolded state is illustrated in FIG. 10A, the separation distance G_{BF} between the dam reinforcing part BFD-D and the main protective layer PF-M in the bent state may be 50 μm or more.

As the dam reinforcing part BFD-D is disposed to be spaced a predetermined distance apart from the main protective layer PF-M, when the electronic device ED-1 is deformed due to folding, even when the main protective layer PF-M is stretched according to a numerical change of the main protective layer PF-M and thus a slip phenomenon occurs at a portion thereof, collision between the main protective layer PF-M and the dam reinforcing part BFD-D may be prevented. Further, a strength of the electronic device may be improved by filling a part of a space between the display module DM and the lower module LM after the main reinforcing part BFD-M is bent.

Referring to FIG. 10B, in an electronic device ED-2 according to an embodiment, a reinforcing layer BFD-b disposed between the main protective layer PF-M and the sub-protective layer PF-S may be spaced apart from the main protective layer PF-M and the sub-protective layer PF-S.

The reinforcing layer BFD-b may be spaced a first separation distance G_{BF}-a apart from the main protective layer PF-M and spaced a second separation distance G_{BF}-b apart from the sub-protective layer PF-S. In an embodiment, the first separation distance G_{BF}-a and the second separation distance G_{BF}-b may be substantially the same.

In another embodiment, the first separation distance G_{BF}-a may be greater than or equal to 50 μm, and the second separation distance G_{BF}-b may be greater than 0 μm and less than 50 μm.

As the reinforcing layer BFD-b is disposed to be spaced a predetermined distance apart from the main protective layer PF-M, when the electronic device ED-2 is deformed due to folding, even when the main protective layer PF-M is stretched according to a numerical change of the main protective layer PF-M and thus a slip phenomenon occurs at a portion thereof, collision between the main protective layer PF-M and the reinforcing layer BFD-b may be prevented. Further, as the reinforcing layer BFD-b is provided with a sufficient thickness between the main protective layer PF-M and the sub-protective layer PF-S, a strength of the bending area may be improved, and thus the electronic device ED-2 may exhibit excellent durability and reliability.

An electronic device ED-2S of FIG. 10C differs from the electronic device ED-2 of FIG. 10B in that the former further includes sub-reinforcing layers SRL-a and SRL-b. The electronic device ED-2S may include the first sub-reinforcing layer SRL-a disposed between the main protective layer PF-M and the reinforcing layer BFD-b and the second sub-reinforcing layer SRL-b disposed between the reinforcing layer BFD-b and the sub-protective layer PF-S.

The same contents as those of the sub-reinforcing layer SRL described with reference to FIGS. 9A and 9B may be applied to the first sub-reinforcing layer SRL-a and the second sub-reinforcing layer SRL-b. The first sub-reinforcing layer SRL-a may alleviate an impact between the main protective layer PF-M and the reinforcing layer BFD-b and exhibit excellent restoration characteristics after deformation is removed. Further, the second sub-reinforcing layer SRL-b may alleviate an impact between the sub-protective layer PF-S and the reinforcing layer BFD-b and exhibit excellent restoration characteristics after deformation is removed.

Because the first sub-reinforcing layer SRL-a and the second sub-reinforcing layer SRL-b have low elastic modulus characteristics, even when a slip phenomenon occurs in the main protective layer PF-M or the sub-protective layer PF-S while the electronic device ED-2S is deformed to a folding-unfolding state, the first sub-reinforcing layer SRL-a and the second sub-reinforcing layer SRL-b may absorb deformation caused by the deformation of the protective layers PF-M and PF-S and thus prevent a deformation stress from being transmitted to the reinforcing layer BFD-b. Accordingly, the electronic device ED-2S according to an embodiment may exhibit excellent durability and reliability characteristics.

FIG. 11A is a view exemplarily illustrating a degree of deformation of components during a folding operation of the electronic device according to an embodiment. FIG. 11B illustrates the amounts of deformation of components in one direction during the folding operation in the components constituting the electronic device.

FIGS. 11A and 11B illustrate the electronic device having a laminated structure of the protective layer PF, the display panel DP, the optical layer RCL, and the window WM as a reference. Further, the window WM may include a base glass WP, a protective film PL, and an interlayer adhesive layer AP-M disposed between the base glass WP and the protective film PL. The electronic device may further include adhesive layers AP1, AP-D, AP-W, and AP-M arranged between the members.

In FIG. 11A, a reference line RL is a line indicating initial states of the members before the folding operation. In FIG. 11A, the slip direction SLD corresponds to deformation directions of the members after the folding operation. Edge lines of the members included in the electronic device may be deformed and located in the slip direction SLD as compared to the reference line RL after the folding operation. For example, an edge of an initial state PFL-I of the protective layer PF may be deformed in the slip direction SLD and positioned as an edge of a deformed state PFL-F.

FIG. 11B illustrates an “image analysis” value identified by directly observing images of amounts of deformation of the members of the electronic device in the initial state and the deformed state and a “simulation” value predicted through simulation.

Referring to FIG. 11B, the amount of deformation in the protective layer PF may be about 50 μm. Accordingly, in the electronic device according to an embodiment, when a separation distance between the reinforcing layer and the main protective layer is 50 μm or more, collision between the reinforcing layer and the protective layer may be prevented.

The electronic device according to an embodiment may include the reinforcing layer that fills at least a portion of an inner bending area to correspond to the bending area of the display module, and thus exhibit excellent durability and improved reliability characteristics. Further, as the reinforcing layer is spaced apart from the main protective layer, even when a slip phenomenon occurs in the components of the electronic device during folding deformation of the electronic device, collision between the reinforcing layer and the slipped components may be prevented. Accordingly, a stress caused by the collision may be prevented from being transmitted to a display area or the like, and thus the electronic device may exhibit excellent operation reliability.

Hereinafter, a method of manufacturing an electronic device according to an embodiment will be described with reference to FIGS. 12 to 20. A description of the method of manufacturing an electronic device according to an embodiment described with reference to FIGS. 12 to 20, which is duplicated with the contents of the electronic device according to an embodiment described with reference to FIGS. 1A to 11B, will not be described again, and a difference therebetween will be mainly described.

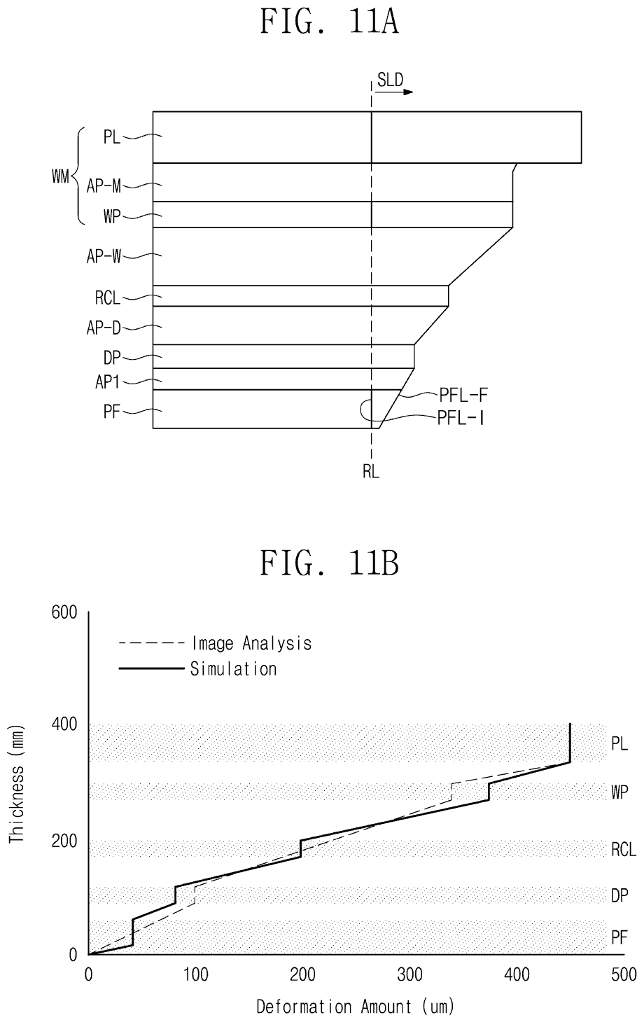

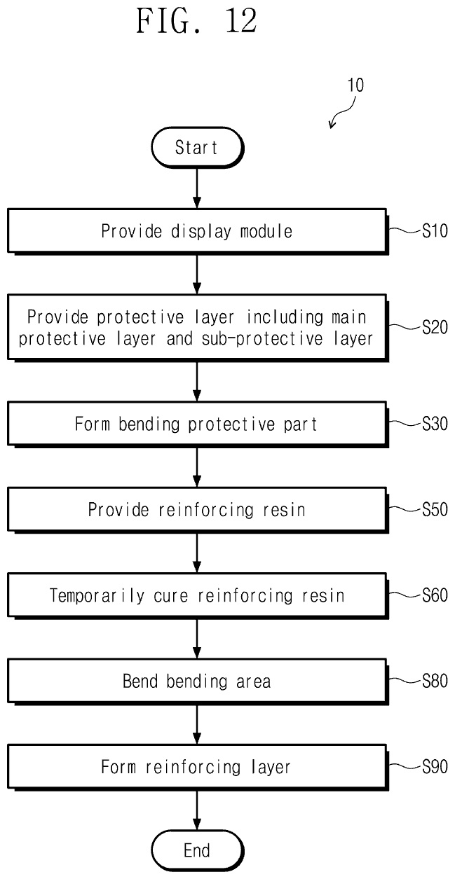

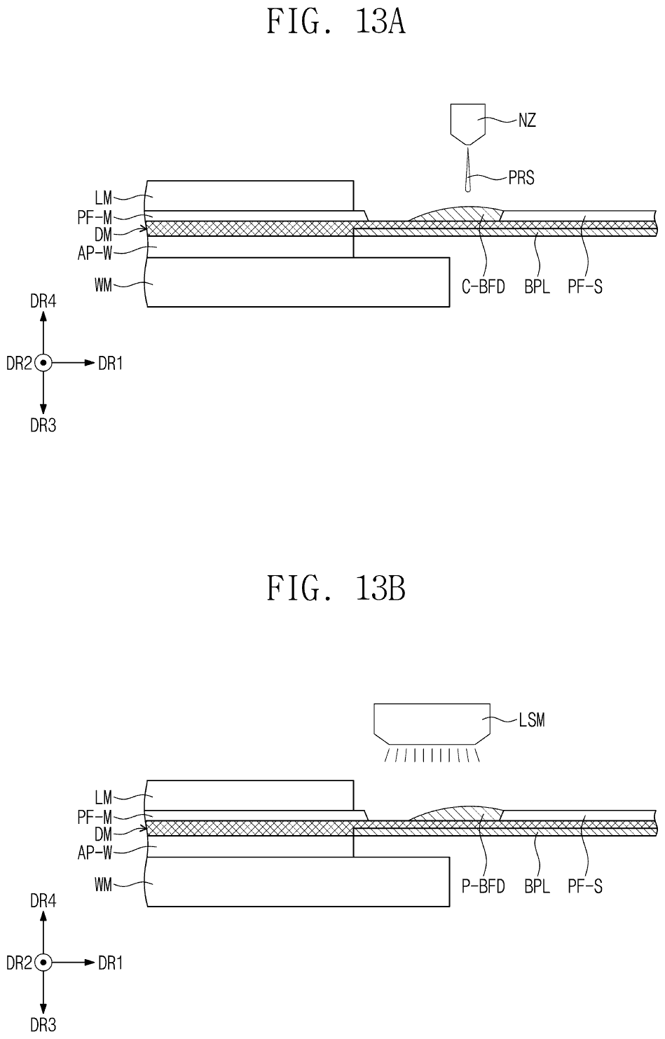

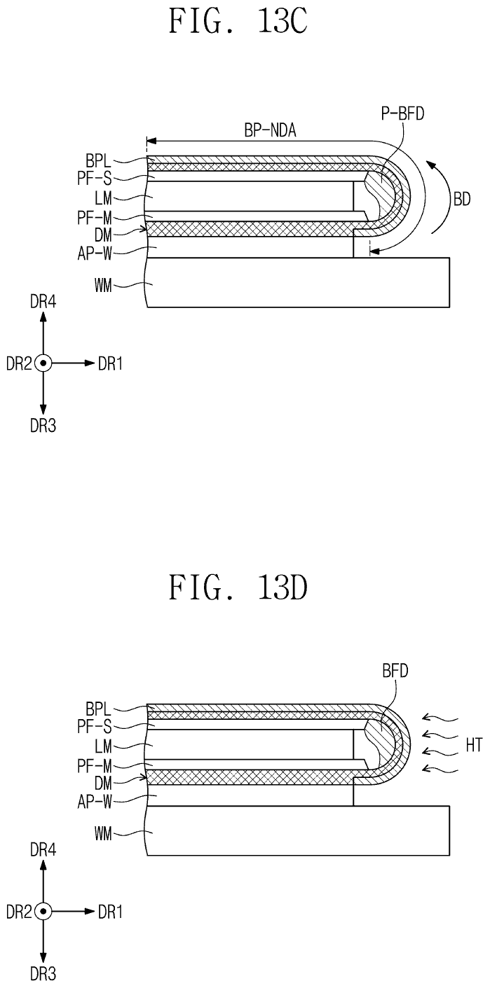

FIG. 12 is a flowchart illustrating a method of manufacturing an electronic device according to an embodiment. FIGS. 13A to 13D are views exemplarily illustrating operations of the method of manufacturing an electronic device according to an embodiment.

The method 10 of manufacturing an electronic device according to an embodiment may include a display module provision operation S10, a protective layer provision operation S20 in which a protective layer includes a main protective layer and a sub-protective layer, a bending protective part formation operation S30, a reinforcing resin provision operation S50, a reinforcing resin temporal curing operation S60, a bending area bending operation S80, and a reinforcing layer formation operation S90.

A display module provided in the method of manufacturing an electronic device may include a display area, a non-display area disposed outside the display area, and a bending area disposed on one side of the non-display area and bent with respect to an imaginary bending axis extending in one direction.

Further, the display module may include a folding display part folded with respect to a folding axis extending in one direction parallel to the bending axis and a first non-folding display part and a second non-folding display part spaced apart from each other with the folding display part interposed therebetween.

The protective layer provision operation S20 may be performed after the display module provision operation S10. A protective layer may be provided under the display module. The protective layer may be separated into a main protective layer and a sub-protective layer. The main protective layer and the sub-protective layer may be spaced apart from each other to define an open area. The main protective layer may be provided to overlap the display area, and the sub-protective layer may be provided to overlap the bending area. The sub-protective layer may overlap at least a portion of the bending area. In the protective layer, the open area may be defined to overlap the bending area.

The method 10 of manufacturing an electronic device according to an embodiment may include the bending protective part formation operation S30. In an embodiment, the bending protective part formation operation S30 may be performed after the protective layer provision operation S20.

The bending protective part may cover and protect a portion of the display module in the bending area. The bending protective part formation operation S30 may include an operation of providing a bending protective part resin and an operation of curing the bending protective part resin.

In the method 10 of manufacturing an electronic device according to an embodiment, a circuit board may be attached after the bending protective part formation operation S30. The circuit board may be connected to a pad or the like disposed in the bending area.

In the method 10 of manufacturing an electronic device according to an embodiment, the reinforcing resin provision operation S50 may be performed after the bending protective part formation operation S30. In another embodiment, before the reinforcing resin provision operation S50, an operation of attaching a window to an upper side of the display module and an operation of attaching a lower module to a lower side of the display module may be performed.

FIG. 13A is a view exemplarily illustrating the reinforcing resin provision operation S50. In the reinforcing resin provision operation S50, a reinforcing resin PRS may be provided to one surface of the display module DM through a nozzle NZ. The reinforcing resin PRS may be provided to be spaced apart from the bending protective part BPL with the display module DM interposed therebetween. The reinforcing resin PRS may be provided under the display module DM. The reinforcing resin PRS may be controlled to be spaced a predetermined distance apart from the main protective layer PF-M. FIGS. 13A to 14, 16A, 16B, 18A, 18B, and 20 are views flipped upside down with respect to FIG. 6.

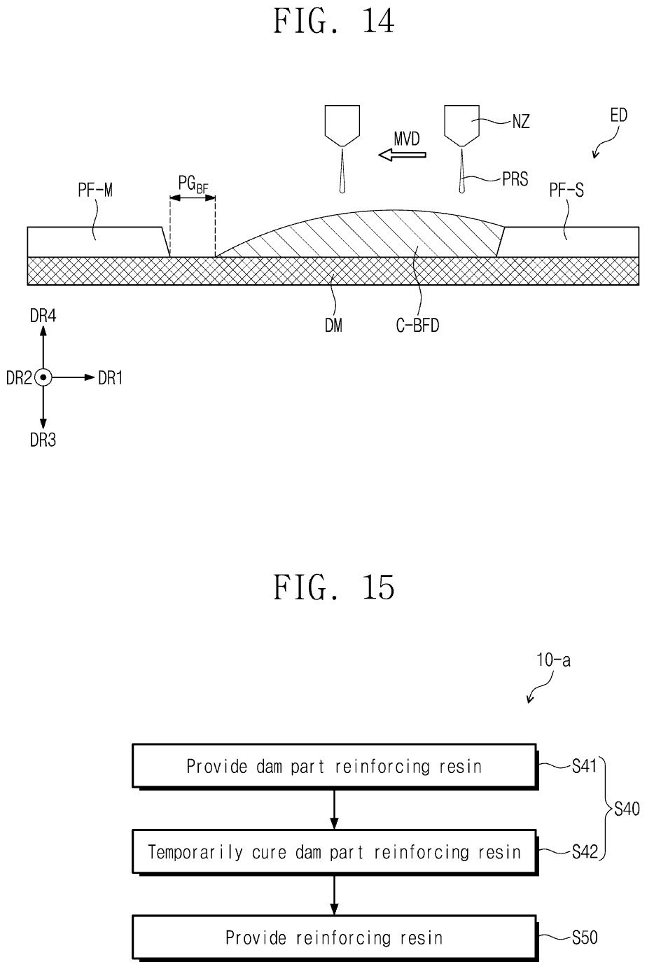

In an embodiment, the sub-protective layer PF-S may function as a dam when the reinforcing resin PRS is provided. FIG. 14 exemplarily illustrates a process operation of the reinforcing resin provision operation S50.

Referring to FIG. 14, in the reinforcing resin provision operation S50, the reinforcing resin PRS may be provided while moving the nozzle NZ in a direction MVD of the main protective layer PF-M, starting from a location adjacent to the sub-protective layer PF-S.

In this case, an application point and an application amount of the reinforcing resin PRS provided through the nozzle NZ may be controlled such that a reinforcing resin coating layer C-BFD and the main protective layer PF-M are spaced a predetermined separation distance PG_{BF} or more from each other. The separation distance PG_{BF} between the reinforcing resin coating layer C-BFD and the main protective layer PF-M may be controlled in consideration of the separation distance G_{BF} (see FIG. 8B) between the main protective layer PF-M and the reinforcing layer BFD (see FIG. 8B) required in a finally manufactured electronic device. The separation distance PG_{BF} between the reinforcing resin coating layer C-BFD and the main protective layer PF-M may be controlled in consideration of contraction or expansion of the reinforcing resin coating layer C-BFD during the reinforcing resin temporal curing operation S60, the bending area bending operation S80, and the reinforcing layer formation operation S90, which are performed later. That is, the application point and the application amount of the reinforcing resin PRS may be controlled in consideration of the separation distance between the reinforcing layer and the main protective layer in a state in which the bending area BP-NDA is bent.

The reinforcing resin temporal curing operation S60 may be performed after the reinforcing resin provision operation S50. FIG. 13B is a view exemplarily illustrating the reinforcing resin temporal curing operation S60. Ultraviolet rays may be radiated to the reinforcing resin coating layer C-BFD provided in the reinforcing resin provision operation S50 using a light radiation device LSM to form a preliminary reinforcing layer P-BFD. The preliminary reinforcing layer P-BFD may be easily deformed in the bending area bending operation S80 that is performed later in a state in which the reinforcing resin is temporarily cured, and the degree of curing the reinforcing resin may be adjusted to the extent that cracks do not occur. The reinforcing resin temporal curing operation S60 may include an operation of controlling flowability of the reinforcing resin PRS by radiating ultraviolet rays to the reinforcing resin.

The bending area bending operation S80 may be performed after the reinforcing resin temporal curing operation S60. FIG. 13C is a view exemplarily illustrating the bending area bending operation S80. In the bending area bending operation S80, the temporarily cured reinforcing resin may be bent toward an inside. The bending area BP-NDA may be bent (BD) such that the preliminary reinforcing layer P-BFD is located between the lower module LM and the display module DM.

The reinforcing layer formation operation S90 may be performed after the bending area of the display module is bent. FIG. 13D is a view exemplarily illustrating the reinforcing layer formation operation S90.

The reinforcing layer formation operation S90 may be an operation of forming the reinforcing layer BFD by bending the preliminary reinforcing layer P-BFD inward and then curing the preliminary reinforcing layer P-BFD that is a reinforcing resin temporarily reinforced in the bent state.

The reinforcing layer formation operation S90 may include a thermal curing operation of curing the preliminary reinforcing layer P-BFD by providing heat HT. Meanwhile, in the reinforcing layer formation operation S90, in order to cure the preliminary reinforcing layer P-BFD, thermal curing or photocuring may be used or both the thermal curing and the photocuring may be used.

An electronic device manufactured by the method of manufacturing an electronic device according to an embodiment, which is described with reference to FIGS. 12 to 14, may include a reinforcing layer configuration as illustrated in FIG. 6 or the like.

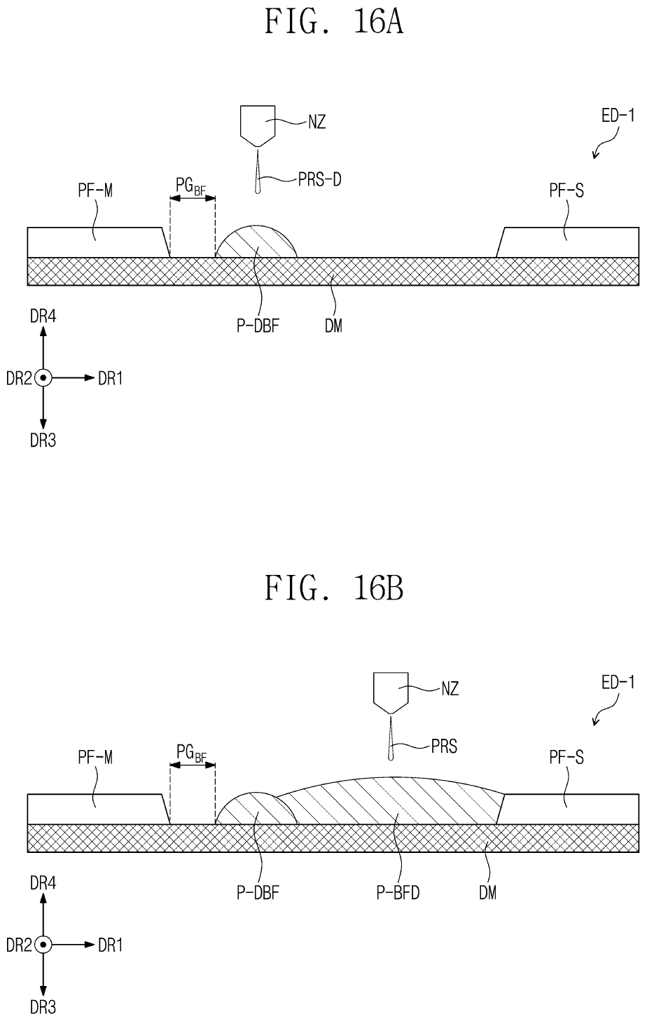

FIG. 15 is a flowchart of a portion of the method of manufacturing an electronic device according to an embodiment. FIGS. 16A and 16B are views exemplarily illustrating operations of the method of manufacturing an electronic device according to an embodiment.

A method 10-a of manufacturing an electronic device according to an embodiment differs from the method 10 of manufacturing an electronic device according to an embodiment illustrated in FIG. 12 in that the former further includes a preliminary dam reinforcing part provision operation S40. The preliminary dam reinforcing part provision operation S40 may include operation S41 of providing a dam part reinforcing resin and operation S42 of temporarily curing the dam part reinforcing resin.

The electronic device ED-1 formed through the manufacturing operations illustrated and described in FIGS. 15 to 16B may have a structure illustrated in FIG. 10A.

Before the reinforcing resin provision operation S50, the operation S41 of providing a dam part reinforcing resin PRS-D at a location spaced apart from the main protective layer PF-M and the sub-protective layer PF-S and the operation S42 of temporarily curing the provided dam part reinforcing resin PRS-D may be performed.

Referring to FIG. 16A, the dam part reinforcing resin PRS-D may be provided through the nozzle NZ. The dam part reinforcing resin PRS-D may be spaced apart from the main protective layer PF-M and the sub-protective layer PF-S. Referring to FIG. 16A, the dam part reinforcing resin PRS-D may be spaced the predetermined separation distance PG_{BF} from the main protective layer PF-M to form a preliminary dam reinforcing part P-DBF. The separation distance PG_{BF} at a point at which the main protective layer PF-M and the dam part reinforcing resin PRS-D are provided may be controlled in consideration of the separation distance G_{BF} between the main protective layer PF-M and the dam reinforcing part BFD-D in a state in which the bending area is bent in the electronic device ED-1 illustrated in FIG. 10A.

The preliminary dam reinforcing part P-DBF may be formed by providing the dam part reinforcing resin PRS-D, radiating ultraviolet rays to the provided dam part reinforcing resin PRS-D, and curing the dam part reinforcing resin PRS-D. The preliminary dam reinforcing part P-DBF may be spaced apart from the main protective layer PF-M and the sub-protective layer PF-S but may be located closer to the main protective layer PF-M.

After the preliminary dam reinforcing part P-DBF is formed, the reinforcing resin provision operation S50 may be performed. The reinforcing resin PRS may be provided between the preliminary dam reinforcing part P-DBF and the sub-protective layer PF-S. The preliminary dam reinforcing part P-DBF may function as a dam that controls flow of the reinforcing resin PRS.

The dam part reinforcing resin PRS-D and the reinforcing resin PRS may include the same material. Accordingly, in a finally cured state, a boundary between the dam reinforcing part BFD-D (see FIG. 10A) and the main reinforcing part BFD-M (see FIG. 10A) may not be distinguished.

Further, in an embodiment, viscosity of the dam part reinforcing resin PRS-D used to form the preliminary dam reinforcing part P-DBF may be relatively high as compared to the reinforcing resin PRS. Because the dam part reinforcing resin PRS-D has a relatively high viscosity characteristic, flow of the dam part reinforcing resin PRS-D is small when the dam part reinforcing resin PRS-D is supplied from the nozzle NZ, and accordingly, only a required area may be easily controlled to be selectively coated with the dam part reinforcing resin PRS-D. Accordingly, the dam part reinforcing resin PRS-D may be provided to form the preliminary dam reinforcing part P-DBF functioning as a dam.

The preliminary reinforcing layer P-BFD may be formed by providing a reinforcing resin between the preliminary dam reinforcing part P-DBF and the sub-protective layer PF-S and temporarily curing the provided reinforcing resin.

After the preliminary dam reinforcing part P-DBF and the preliminary reinforcing layer P-BFD are formed, the bending area bending operation S80 (see FIG. 12) and the reinforcing layer formation operation S90 (see FIG. 12) may be sequentially performed. The reinforcing layer formation operation S90 (see FIG. 12) and an operation of forming the dam reinforcing part by curing the temporarily cured dam part reinforcing resin may be performed in the same process operation. That is, in the case of the method 10-a of manufacturing an electronic device according to an embodiment, the preliminary dam reinforcing part provision operation S40 is performed before the reinforcing resin provision operation S50, and thus an application area of the reinforcing resin PRS may be easily controlled. The preliminary dam reinforcing part P-DBF may be preferentially provided, and thus a separation distance between the main protective layer PF-M and the reinforcing layer may be easily controlled. Accordingly, the electronic device ED-1 manufactured by the method 10-a of manufacturing an electronic device according to an embodiment may include the reinforcing layer that effectively protects the bending area and is stably spaced apart from the main protective layer, and thus may have improved durability and improved reliability during a folding operation.

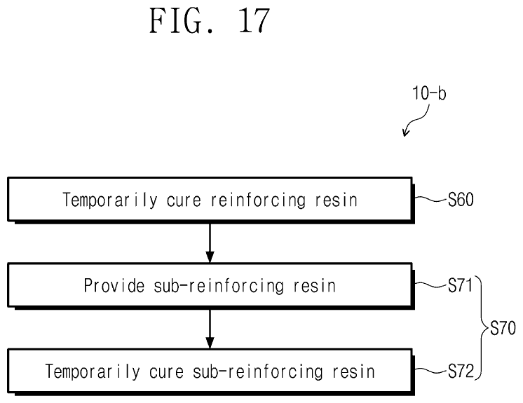

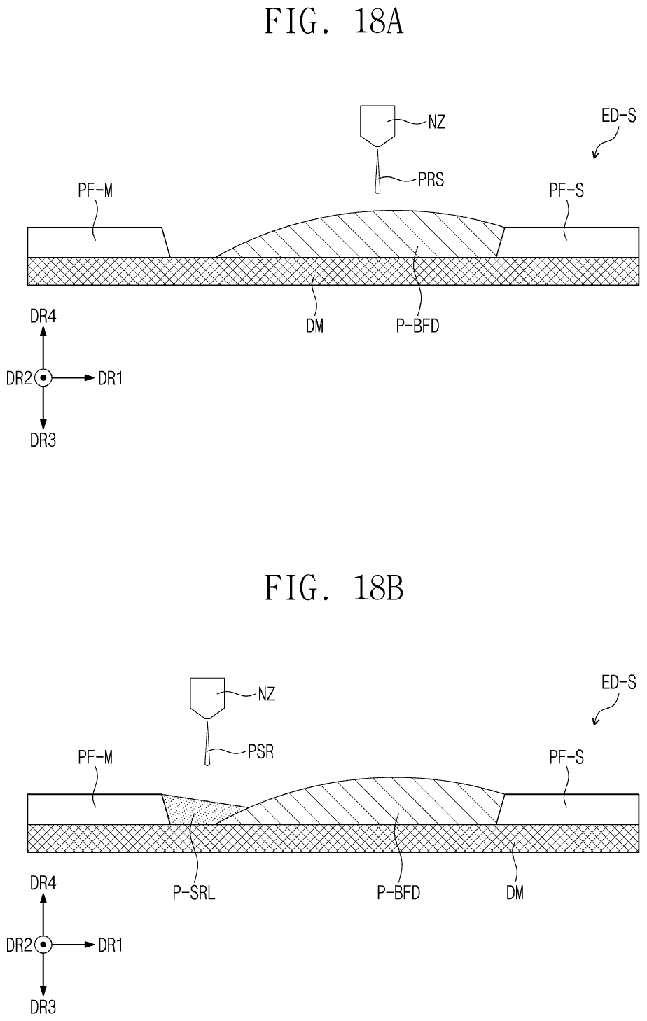

FIG. 17 is a flowchart of a portion of the method of manufacturing an electronic device according to an embodiment. FIGS. 18A and 18B are views exemplarily illustrating operations of the method of manufacturing an electronic device according to an embodiment.

A method 10-b of manufacturing an electronic device according to an embodiment differs from the method 10 of manufacturing an electronic device according to an embodiment illustrated in FIG. 12 in that the former further includes a preliminary sub-reinforcing layer provision operation S70. The preliminary sub-reinforcing layer provision operation S70 may include operation S71 of providing a sub-reinforcing resin and operation S72 of temporarily curing the sub-reinforcing resin.

The electronic device ED-S formed through the manufacturing operations illustrated and described in FIGS. 17 to 18B may have a structure illustrated in FIG. 9B.

FIG. 18A exemplarily illustrates an operation of providing the preliminary reinforcing layer P-BFD. The preliminary reinforcing layer P-BFD may be formed by providing the reinforcing resin PRS and temporarily curing the provided reinforcing resin PRS.

In the method 10-b of manufacturing an electronic device according to an embodiment, the preliminary sub-reinforcing layer provision operation S70 may be performed after the reinforcing resin temporal curing operation S60. The preliminary sub-reinforcing layer provision operation S70 may include operation S71 of providing a sub-reinforcing resin between the temporarily cured reinforcing rein and the main protective layer and operation S72 of temporarily curing the provided sub-reinforcing resin.

FIG. 18B exemplarily illustrates the preliminary sub-reinforcing layer provision operation S70. Referring to FIG. 18B, a sub-reinforcing resin PSR may be provided through the nozzle NZ, and the sub-reinforcing resin PSR may be provided between the main protective layer PF-M and the preliminary reinforcing layer P-BFD. The sub-reinforcing resin PSR may fill a space between the main protective layer PF-M and the preliminary reinforcing layer P-BFD.

The provided sub-reinforcing resin PSR may be temporarily cured to form a preliminary sub-reinforcing layer P-SRL. The preliminary sub-reinforcing layer P-SRL may be formed by partially curing the provided sub-reinforcing resin PSR with ultraviolet rays.

After the preliminary sub-reinforcing layer P-SRL and the preliminary reinforcing layer P-BFD are formed, the bending area bending operation S80 (see FIG. 12) and the reinforcing layer formation operation S90 (see FIG. 12) may be sequentially performed. The reinforcing layer formation operation S90 (see FIG. 12) and an operation of forming a sub-reinforcing layer by curing the temporarily cured sub-reinforcing resin may be performed in the same process operation. That is, in the method 10-b of manufacturing an electronic device according to an embodiment, the preliminary sub-reinforcing layer provision operation S70 may be performed after the reinforcing resin temporal curing operation S60, and thus the bending area exposed between the main protective layer PF-M and the sub-protective layer PF-S may be effectively protected.

The sub-reinforcing layer SRL and the reinforcing layer BFD finally formed after the reinforcing layer formation operation S90 may have different modulus characteristics. Because the sub-reinforcing layer SRL has relatively low elastic modulus properties compared to the reinforcing layer BFD, collision between the display module DM and the reinforcing layer BFD during the folding operation of the electronic device ED-S may be prevented. Alternatively, the sub-reinforcing layer SRL may have low elastic modulus characteristics, and thus may absorb a stress generated during the folding operation of the electronic device ED-S or may absorb an impact caused by collision between the display module DM and the reinforcing layer BFD. Accordingly, the electronic device ED-S manufactured by the method 10-b of manufacturing an electronic device according to an embodiment may effectively protect the bending area and thus have improved durability and improved reliability during the folding operation.

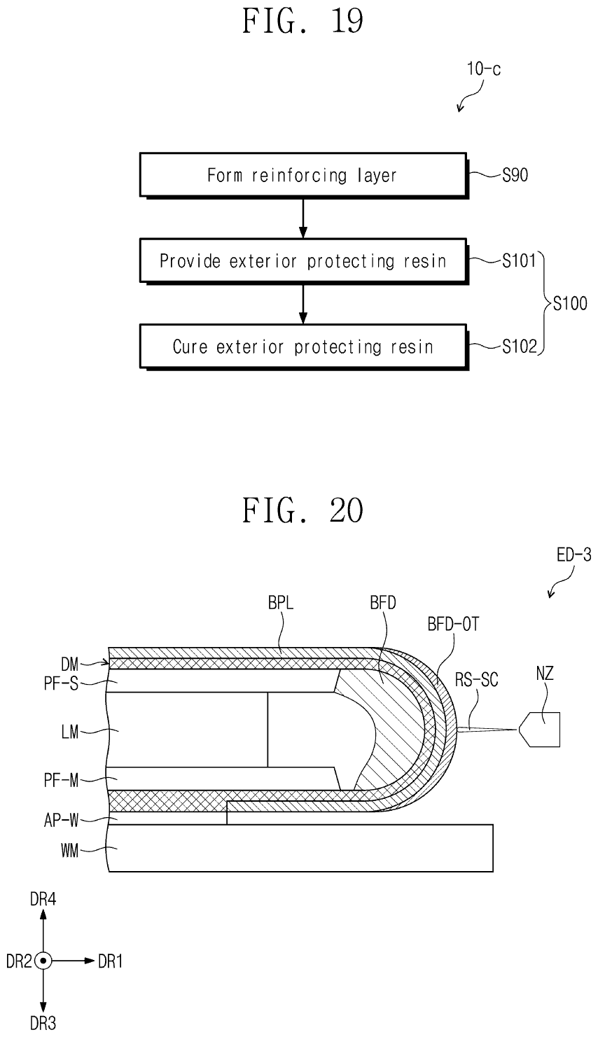

FIG. 19 is a flowchart of a portion of the method of manufacturing an electronic device according to an embodiment. FIG. 20 is a view exemplarily illustrating an operation of the method of manufacturing an electronic device according to an embodiment.

A method 10-c of manufacturing an electronic device according to an embodiment differs from the method 10 of manufacturing an electronic device according to an embodiment illustrated in FIG. 12 in that the former further includes an exterior reinforcing layer formation operation S100. The exterior reinforcing layer formation operation S100 may include operation S101 of providing an exterior protective resin and operation S102 of curing the exterior protective resin.

An electronic device ED-3 formed through the manufacturing operations illustrated and described in FIG. 19 may have a structure illustrated in FIG. 20.

Referring to FIG. 20, the exterior reinforcing layer formation operation S100 may include operation S101 of providing an exterior reinforcing resin RS-SC outside the bending protective part BPL and operation S102 of curing the exterior reinforcing resin RS-SC. The exterior reinforcing resin RS-SC may be cured by ultraviolet rays or heat to form an exterior reinforcing layer BFD-OT.

The exterior reinforcing resin RS-SC may be provided through the nozzle NZ to cover at least a portion of the bending protective part BPL. The exterior reinforcing layer BFD-OT may be spaced apart from the reinforcing layer BFD with the display module DM interposed therebetween. The exterior reinforcing resin RS-SC may include the same material as the reinforcing resin PRS.

The bending area of the display module DM may be additionally protected by the exterior reinforcing layer BFD-OT, and accordingly, the electronic device ED-3 manufactured by the method 10-c of manufacturing an electronic device according to an embodiment may effectively protect the bending area, and thus may have improved durability and improved reliability during the folding operation.

The electronic device according to an embodiment includes a foldable folding area, and the electronic device may include the protective layer which overlaps the bending area located on one side of the non-display area of the display module and in which an open area is defined and the reinforcing layer spaced apart from the protective layer in the open area of the protective layer, and thus have improved durability and excellent reliability.

The method of manufacturing an electronic device according to an embodiment may include an operation of providing the reinforcing resin to the bending area of the display module in which the protective layer is not disposed, temporarily curing the provided reinforcing resin, bending the bending area, and finally forming the reinforcing layer by curing the temporarily cured reinforcing resin and thus may be used to manufacture the electronic device having improved durability even when the electronic device is deformed and used during the folding operation.

An electronic device according to an embodiment may include a reinforcing layer disposed under a display module and spaced apart from a protective layer overlapping a display area, thereby exhibiting excellent durability and improved operation reliability.

A method of manufacturing an electronic device according to an embodiment may be used to manufacture an electronic device in which a reinforcing resin is provided in an open area between protective layers such that the reinforcing resin is spaced apart from the protective layer, the reinforcing layer is then formed, and thus a bending area has improved durability.

Although the description has been made above with reference to an embodiment of the present disclosure, it may be understood that those skilled in the art or those having ordinary knowledge in the art may variously modify and change the present disclosure without departing from the spirit and technical scope of the present disclosure described in the appended claims.

Accordingly, the technical scope of the present disclosure is not limited to the detailed description of the specification, but should be defined by the appended claims.

What is claimed is:

1. An electronic device comprising a foldable folding area and a first non-folding area and a second non-folding area spaced apart from each other with the folding area interposed therebetween, the electronic device comprising:
a display module including a display area, a non-display area disposed outside the display area, and a bending area disposed on one side of the non-display area and bent with respect to an imaginary bending axis extending in one direction;
a protective layer including a main protective layer overlapping the display area under the display module and a sub-protective layer spaced apart from the main protective layer and overlapping the bending area; and
a reinforcing layer overlapping the display module, spaced apart from the main protective layer and disposed between the main protective layer and the sub-protective layer.

2. The electronic device of claim 1, wherein a separation distance between the main protective layer and the reinforcing layer is 50 micrometers (μm) or more.

3. The electronic device of claim 1, wherein the reinforcing layer includes a dam reinforcing part spaced a predetermined distance apart from the main protective layer and a main reinforcing part disposed between the dam reinforcing part and the sub-protective layer, and
wherein an upper dam surface of the dam reinforcing part includes a curved surface having a radius of curvature different from a radius of curvature of an upper main part surface of the main reinforcing part.

4. The electronic device of claim 1, further comprising:
a sub-reinforcing layer disposed between the reinforcing layer and the main protective layer,
wherein an elastic modulus of the sub-reinforcing layer is smaller than an elastic modulus of the reinforcing layer.

5. The electronic device of claim 4, wherein the elastic modulus of the sub-reinforcing layer is 100 megapascals (MPa) or less.

6. The electronic device of claim 1, wherein the reinforcing layer is spaced apart from the main protective layer and the sub-protective layer, and
wherein a separation distance between the main protective layer and the reinforcing layer is 50 μm or more.

7. The electronic device of claim 6, further comprising:
a sub-reinforcing layer disposed between the reinforcing layer and the main protective layer and between the reinforcing layer and the sub-protective layer,
wherein an elastic modulus of the sub-reinforcing layer is smaller than an elastic modulus of the reinforcing layer.

8. The electronic device of claim 1, wherein the display module includes a bending protective part disposed in the bending area, and
wherein the electronic device further comprises an exterior reinforcing layer spaced apart from the reinforcing layer with the display module interposed therebetween and disposed on the bending protective part.

9. The electronic device of claim 1, further comprising:
a lower module disposed under the protective layer,
wherein the reinforcing layer fills 40% or more of an inner space defined by a side surface of the lower module and the bending area.

10. The electronic device of claim 1, further comprising:
a window disposed on the display module and covering an entirety of the display area, the non-display area, and the bending area.

11. A method of manufacturing an electronic device, the method comprising:
providing a display module including a display area, a non-display area disposed outside the display area, and a bending area disposed on one side of the non-display area and bent with respect to an imaginary bending axis extending in one direction;
providing a protective layer including a main protective layer overlapping the display area and a sub-protective layer spaced apart from the main protective layer and overlapping at least a portion of the bending area;
forming a bending protective part on the bending area;
providing a reinforcing resin between the main protective layer and the sub-protective layer such that the reinforcing resin is disposed spaced apart from the main protective layer under the display module;
temporarily curing the reinforcing resin;
bending the bending area such that the temporarily cured reinforcing resin faces an inside; and
forming a reinforcing layer by curing the temporarily cured reinforcing resin in a bent state.

12. The method of claim 11, wherein the temporarily curing of the reinforcing resin includes controlling flowability of the reinforcing resin by radiating ultraviolet rays to the reinforcing resin.

13. The method of claim 11, wherein the forming of the reinforcing layer includes thermally curing the temporarily cured reinforcing resin.

14. The method of claim 11, further comprising:
before the providing of the reinforcing resin:
providing a dam part reinforcing resin at a location spaced apart from the main protective layer and the sub-protective layer; and
temporarily curing the dam part reinforcing resin,
wherein the reinforcing resin is provided between the temporarily cured dam part reinforcing resin and the sub-protective layer.

15. The method of claim 14, wherein the forming of the reinforcing layer and forming a dam reinforcing part by curing the temporarily cured dam part reinforcing resin are performed in a same process operation.

16. The method of claim 14, wherein the reinforcing resin and the dam part reinforcing resin include a same material.

17. The method of claim 11, further comprising:
after the temporarily curing of the reinforcing resin:
providing a sub-reinforcing resin between the temporarily cured reinforcing resin and the main protective layer; and
temporarily curing the provided sub-reinforcing resin.

18. The method of claim 17, wherein the forming of the reinforcing layer and forming a sub-reinforcing layer by curing the temporarily cured sub-reinforcing resin are performed in a same process operation.

19. The method of claim 16, wherein the bending area of the display module includes the bending protective part, and
wherein the method further comprises, after the forming of the reinforcing layer:
providing an exterior reinforcing resin outside the bending protective part; and
curing the exterior reinforcing resin.

20. The method of claim 11, wherein the display module includes a folding display part folded with respect to a folding axis parallel to the bending axis and a first non-folding display part and a second non-folding display part spaced apart from each other with the folding display part interposed therebetween.
